(19) United States
(12) Patent Application Publication
(10) Pub. No.: US 2026/0327465 A1
(43) Pub. Date: Oct. 22, 2026

(54) BIOADHESIVE POLYMER SEMICONDUCTOR FILMS AND TRANSISTORS FOR INTIMATE BIOINTERFACES

(71) Applicant: The University of Chicago, Chicago, IL (US)

(72) Inventors: Sihong WANG, Chicago, IL (US); Nan LI, Chicago, IL (US)

(73) Assignee: The University of Chicago, Chicago, IL (US)

(21) Appl. No.: 19/485,499

(22) PCT Filed: May 29, 2024
(86) PCT No.: PCT/US2024/031363

§ 371 Date: Nov. 18, 2025

Related U.S. Application Data
(60) Provisional application No. 63/504,831, filed on May 30, 2023.

(51) Int. Cl. C09J 123/06; C09J 5/06; G01N 27/414; H10K 10/46; H10K 10/88; H10K 71/12; H10K 77/10; H10K 85/10

(52) U.S. Cl. CPC C09J 123/06; C09J 5/06; G01N 27/4145; H10K 10/484; H10K 10/88; H10K 71/12; H10K 85/113; C09J 2203/326; C09J 2301/50; C09J 2423/04; C09J 2481/00; H10K 77/111

(57) ABSTRACT

Bioadhesive polymer semiconductor (“BASC”) films, including a bioadhesive polymer and a semiconducting polymer, that is a double-network film, are provided herein. Methods of making the film, including in situ preparation of the bioadhesive polymer, are further provided. Organic electrochemical transistors including the film are further provided.

### STATEMENT REGARDING FEDERALLY FUNDED RESEARCH

This invention was made with government support under 1DP2EB034563 awarded by the National Institutes of Health, 2105367 awarded by the National Science Foundation, and N00014-21-1-2266 awarded by the Office of Naval Research. The government has certain rights in the invention.

### TECHNICAL FIELD

The present disclosure relates to polymer films.

### BACKGROUND

Integrating biocompatible electronic devices with living biological tissues is emerging as a highly promising avenue for achieving real-time measurement of biological signals with high spatiotemporal resolutions for biological studies and health monitoring. An overarching goal for the development of bioelectronic devices is to achieve conformable and stable interfacing between a sensing surface and a tissue, which may provide effective transduction of bio-signals from the tissue to a device. For interface bonding that necessitates the adhesion property of electronic materials to wet tissue surfaces, very little progress has been reported, with successes limited only to conductors. Conductors may only be used for passive sensing with moderate sensitivity.

For higher sensitivity, transistor-based active sensing devices may provide high amplification, low operation voltage, intrinsic compatibility with ion-based biological events, and the possibility of achieving tissue-like stretchability. The interfacial impedance for such bio-signal transduction may be determined by the microscopic distance between the semiconducting channel and a tissue surface, so the most desired interfacing is to have the semiconducting channel adhere directly to the tissue surface. However, properties of adhesion to wet bio-tissues have never been realized for semiconducting polymers.

Thus, there is a need for bioadhesive polymer films that may form robust and rapid adhesion with bio-tissues under gentle pressure, while providing high charge-carrier mobility. Further, there is a need to ensure the accessibility of bioadhesive groups on the surface of bioadhesive polymer films. Further, there is a need for bioadhesive polymers of bioadhesive polymer films to have co-processability with semiconducting polymers that are typically soluble in organic solvents. Further, there is a need for a double network morphology formed through phase separation not to block a charge transport pathway upon application of bioadhesive polymer films. Further, there is a need to minimize aqueous swellability of bioadhesive polymer films resulting from water adsorption from a tissue surface to minimize impact on electrical performance and inter-layer strain mismatch.

### SUMMARY

In an example, the present disclosure provides a bioadhesive polymer semiconductor (“BASC”) film, including: a semiconducting polymer; and a bioadhesive polymer. The film is a multi-network film.

In another example, the present disclosure provides a method of making a bioadhesive polymer semiconductor (BASC) film, including: preparing a solution of a semiconducting polymer; adding a monomer to the solution to provide a combined solution; applying the combined solution to a substrate to provide a coated substrate; exposing the coated substrate to ultraviolet radiation to provide a crosslinked film; and heating the crosslinked film to provide the BASC film.

In yet another example, the present disclosure provides a method of making a bioadhesive polymer semiconductor (BASC) film, including: preparing a solution of a semiconducting polymer; adding a pre-polymerized bioadhesive polymer to the solution to provide a combined solution; applying the combined solution to a substrate to provide a coated substrate; and heating the coated substrate to provide the BASC film.

In yet another example, the present disclosure provides an organic electrochemical transistor (“OECT”), including a bioadhesive polymer semiconductor (BASC) film, the film including: a semiconducting polymer; and a bioadhesive polymer. The film is a multi-network film.

Further areas of applicability will become apparent from the description provided herein. It should be understood that the description and specific examples are intended for purposes of illustration only and are not intended to limit the scope of the present disclosure.

### DRAWINGS

In order that the present disclosure may be well understood, there will now be described various forms thereof, given by way of example, reference being made to the accompanying drawings. The components in the figures are not necessarily to scale.

FIG. 1 illustrates a schematic diagram for the preparation of an example of a bioadhesive polymer semiconductor (“BASC”) film, prepared according to the principles of the present disclosure;

FIG. 2 illustrates water-absorption-resulted mass increase for examples of bioadhesive polymers (“BAPs”), prepared according to the principles of the present disclosure;

FIG. 3 illustrates dimensional swelling of examples of BAPs, prepared according to the principles of the present disclosure;

FIG. 4 illustrates interfacial toughness of adhesion between an example of a BASC film and an amine-functionalized, dry glass substrate, in comparison to an example of a neat p(g2T-T) film, and an example of a BAP film, prepared in accordance with the principles of the present disclosure;

FIG. 5 illustrates 180°-peeling tests of the adhesion of examples of BASC, BAP, and p(g2T-T) films on amine-treated glass, prepared in accordance with the principles of the present disclosure;

FIG. 6 illustrates 2*Force/width vs. strain curves for 180°-peeling tests of the adhesion of examples of BASC-NHS films with different blending ratios on amine-treated glasses, prepared in accordance with the principles of the present disclosure;

FIG. 7 illustrates interfacial toughness of the adhesion of examples of BASC-NHS films with different blending ratios on amine-treated glass, prepared in accordance with the principles of the present disclosure;

FIG. 8 illustrates interfacial toughness between various amine-functionalized dry substrates and examples of BASC and p(g2T-T) films, prepared in accordance with the principles of the present disclosure;

FIG. 9 illustrates 180°-peeling tests of the adhesion of examples of BASC films on various synthetic surfaces, prepared in accordance with the principles of the present disclosure;

FIG. 10 illustrates interfacial toughness achieved by examples of BASC, BAP, and PAAc films with different types of side chains, prepared in accordance with the principles of the present disclosure;

FIG. 11 illustrates interfacial toughness and shear strength of the adhesion between wet porcine muscle tissues and examples of BASC, BASC-COOH, BASC-NHS, and neat p(g2T-T) films, prepared in accordance with the principles of the present disclosure;

FIG. 12 illustrates interfacial toughness and shear strength between wet porcine muscle tissues and examples of BASC films of different blending compositions, prepared in accordance with the principles of the present disclosure;

FIG. 13 illustrates transfer curves from an example of a BASC film and an example of a p(g2T-T) film serving as an example of an organic electrochemical transistor (“OECT”) channel (V_{g}=gate voltage, Iₐ=drain current, V_{d}=drain voltage, gₘ=transconductance), prepared in accordance with the principles of the present disclosure;

FIG. 14 illustrates charge-carrier mobility and gₘ for examples of BASC and p(g2T-T) films, prepared in accordance with the principles of the present disclosure;

FIG. 15 illustrates normalized UV-Vis absorption of examples of BASC and p(g2T-T) films, prepared in accordance with the principles of the present disclosure;

FIG. 16 illustrates areal impedance of an example of a BASC film, an example of a p(g2T-T) film, and an example of a bilayer p(g2T-T) film coated with a BAP layer (4.5μ thick), prepared in accordance with the principles of the present disclosure;

FIG. 17 illustrates EIS measures of an example of a neat p(g2T-T) film, and two examples of BASC films with a double-network design, and bilayer coating of two-types of BAP on the surfaces, prepared in accordance with the principles of the present disclosure;

FIG. 18 illustrates transfer curves of examples of BASC films in the pristine state, stretched to 100% strain for 1 cycle, and stretched to 100% strain for 100 cycles, prepared in accordance with the principles of the present disclosure, measured with V_{d}=−0.6 V;

FIG. 19 illustrates calculated fibrotic capsule thickness (statistical significance and P values determined by two-sided Student's t-test);

FIG. 20 illustrates transfer curves for an example of a fully-bioadhesive OECT, prepared in accordance with the principles of the present disclosure, under 0% and 50% strains;

FIG. 21 illustrates electrical performance of an example of a fully-bioadhesive OECT, prepared in accordance with the principles of the present disclosure, during stretching from 0% to 40% strain;

FIG. 22 illustrates electrical performance of an example of a fully-bioadhesive OECT, prepared in accordance with the principles of the present disclosure, during repeated stretching cycles;

FIG. 23 illustrates shear strength of the adhesion between an example of a fully-adhesive OECT, prepared in accordance with the principles of the present disclosure, on the porcine muscle tissue, in comparison to an example of an OECT with a non-bioadhesive surface;

FIG. 24 illustrates a ¹H NMR spectrum (400 MHz, CDCl₃) of Compound 1, prepared in accordance with the principles of the present disclosure;

FIG. 25 illustrates a ¹³C NMR spectrum (101 MHz, CDCl₃) of Compound 1, prepared in accordance with the principles of the present disclosure;

FIG. 26 illustrates a ¹H NMR spectrum (400 MHz, CDCl₃) of Compound 2 (monomer of formula (II)), prepared in accordance with the principles of the present disclosure;

FIG. 27 illustrates a ¹³C NMR spectrum (101 MHz, CDCl₃) of Compound 2 (monomer of formula (II)), prepared in accordance with the principles of the present disclosure;

FIG. 28 illustrates a ¹H NMR spectrum (400 MHz, CDCl₃) of Compound 3 (monomer of formula (III)), prepared in accordance with the principles of the present disclosure;

FIG. 29 illustrates a ¹³C NMR spectrum (101 MHz, CDCl₃) of Compound 3 (monomer of formula (III)), prepared in accordance with the principles of the present disclosure;

FIG. 30 illustrates a ¹H NMR spectrum (400 MHz, CDCl₃) of polymer p(g2T-T), prepared in accordance with the principles of the present disclosure; and

FIG. 31 illustrates a fabrication process of an example of a fully bioadhesive OECT sensor, prepared in accordance with the principles of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses.

In describing elements of the present disclosure, the terms “1^{st},” “2^{nd},” “first,” “second,” “A,” “B,” “(a),” “(b),” and the like may be used herein. These terms are only used to distinguish one element from another element, but do not limit the corresponding elements irrespective of the nature or order of the corresponding elements.

Numerical values, including endpoints of ranges, may be expressed herein as approximations preceded by the term “about,” “approximately,” or the like. In such cases, other examples include the particular numerical values. Regardless of whether a numerical value is expressed as an approximation, two examples are included in this disclosure: one expressed as an approximation, and another not expressed as an approximation. It will be further understood that an endpoint of each range is significant both in relation to another endpoint, and independently of another endpoint.

The uses of the terms “a” and “an” and “the” and similar referents in the context of describing the present disclosure (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein may be performed in any suitable order unless otherwise indicated herein or otherwise clearly contradicted by context.

As used herein, the terms “comprise(s),” “include(s),” “having,” “has,” “can,” “contain(s),” and variants thereof, are intended to be open-ended transitional phrases, terms, or words that do not preclude the possibility of additional acts, structures, elements, or components. The present description also contemplates other embodiments “comprising,” “consisting of,” and “consisting essentially of” the examples or elements presented herein, whether explicitly set forth or not.

As used herein, the term “about,” when used in the context of a numerical value or range set forth means a variation of ±15%, or less, of the numerical value. For example, a value differing by ±15%, ±14%, ±10%, or ±5%, among others, would satisfy the definition of “about,” unless more narrowly defined in particular instances.

As used herein, the term “bioadhesive” refers to a material that may adhere to a biological tissue.

As used herein, the term “reduction-oxidation,” and the portmanteau thereof, “redox,” refer to a type of chemical reaction in which the oxidation states of atoms within reagents change. “Oxidation” refers to the loss of electrons or an increase in the oxidation state of a reagent or atoms thereof. “Reduction” refers to the gain of electrons or a decrease in the oxidation state of a reagent or atoms thereof. Examples of redox reactions may include “electron-transfer” redox reactions in which electrons flow from the reducing agent to the oxidizing agent. The terms “redox-active,” “redox activity,” and “redox potential” refer to a measure of the tendency of a chemical species to acquire electrons from, or lose electrons to, an electrode and therefore be reduced or oxidized, respectively.

The term “π-conjugated” refers to an electronic characteristic of an organic compound in which carbon-carbon double or triple bonds are adjacent to one another, separated only by a carbon-carbon single bond. The simplest π-conjugated organic compound is 1,3-butadiene, shown below, in which the adjacent double bonds result in electrons delocalized across the π orbitals of all four carbons:

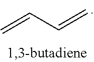

The present disclosure provides examples of bioadhesive polymer semiconductor (“BASC”) films that may form robust and rapid adhesion with biological tissues, such as a tissue of a heart, a lung, or a spleen, under gentle pressure while providing high charge-carrier mobility. In certain examples, the adhesion may be at least 10 times stronger than a polymer semiconductor. In certain examples, the BASC films may include a double-network structure formed by a semiconducting polymer and a separate tissue-adhesive polymer. An advantage of the BASC films of the present disclosure may be that bioadhesive groups of the BASC films are accessible on the surface of the films. Alternatively, or additionally, an advantage of the BASC films of the present disclosure may be co-processability of semiconducting polymers and tissue-adhesive polymers in organic solvents. Alternatively, or additionally, an advantage of the BASC films of the present disclosure may be that a double-network structure of the films does not block a charge transport pathway. Alternatively, or additionally, an advantage of the BASC films of the present disclosure may be that the aqueous swellabilities of the films, due to removing fluid from a surface of a tissue as a result of water adsorption, are moderate, and result in minimal impact to the electrical performance and avoidance of interlayer strain mismatch. Alternatively, or additionally, an advantage of the BASC films of the present disclosure may be a tissue-like modulus (for example <10 kPA) of the films. Alternatively, or additionally, an advantage of the BASC films of the present disclosure may be a high charge-carrier mobility of at least 0.5 cm²·V⁻¹·s⁻¹ and a transistor-level transconductance compared to a polymer semiconductor. Alternatively, or additionally, an advantage of the BASC films of the present disclosure may be abrasion resistance of the films. Alternatively, or additionally, an advantage of the BASC films of the present disclosure may be a stretchability above 100% strain. Alternatively, or additionally, an advantage of the BASC films of the present disclosure may be that a fully-bioadhesive and stretchable transistor sensor may be interfaced with biological tissue for stable signal recording. Alternatively, or additionally, an advantage of the BASC films of the present disclosure may be that the bioadhesive polymers may be polymerized in situ, which may achieve better percolation connectivity of the p(g2T-T) phase.

In an example, BASC films may include a bioadhesive polymer (“BAP”) that may form a double-network film with a semiconducting polymer. In certain examples, the bioadhesive polymer may include a polyethylene backbone. In other examples, the polyethylene backbone may include long linear side chains. Examples of linear side chains may include alkyl or poly(ethyleneglycol) units including tetra(ethylene glycol) (“TEG”) units. In still other examples, the long linear side chains may be terminated by a functional group. Examples of functional groups may include carboxylic acids (—CO₂H) and N-hydroxysuccinmide (“NHS”) ester. In still other examples, monomers making up the bioadhesive polymer of formula (I) may be monomers of formulae (II) (“ACTEGCOOH”) and (III) (“ACTEGNHS”) in a ratio of a:b.

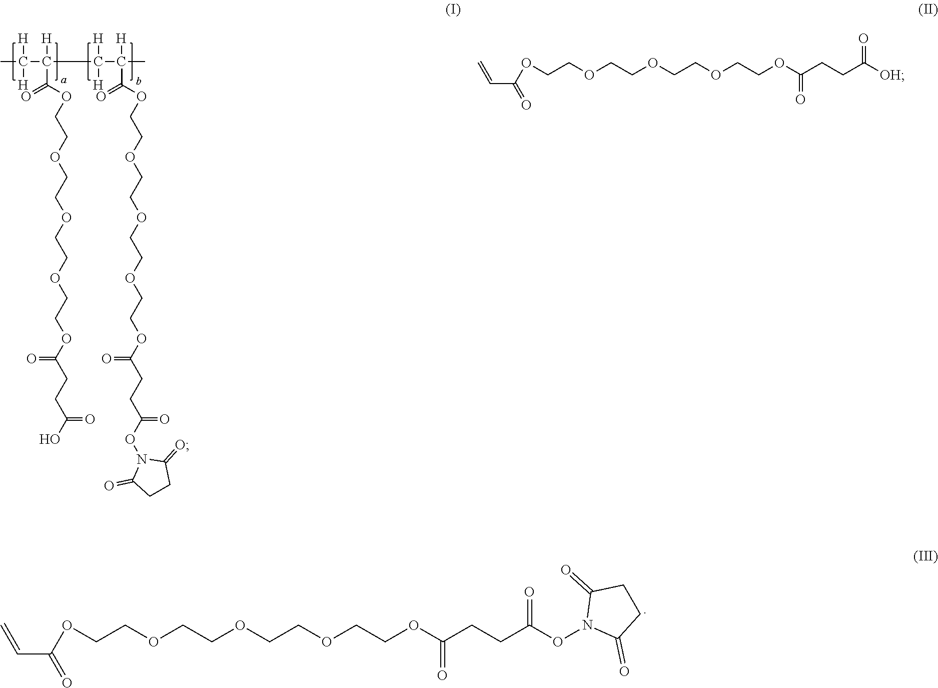

In certain examples, the semiconducting polymer may be redox-active. In other examples, the semiconducting polymer may include a π-conjugated polymer backbone. In still other examples, the semiconducting polymer may include non-conjugated side-chain units. In still other examples, the non-conjugated side-chain units may include alkyl or oligo(ethylene glycol) side-chain units. Examples of the semiconducting polymer may include poly(3,3′-bis(2-(2-(2-methoxyethoxy)ethoxy)ethoxy)-2,2′:5′,2″-terthiophene (“p(g2T-T)”), which has formula (IV):

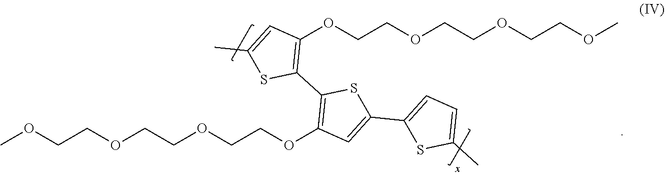

In certain examples, BASC films may result from blending p(g2T-T) and monomers of formulae (II) and (III) in a controlled ratio of a:b in a solution, spin-coating the solution onto a substrate as a thin film, and polymerizing and cross-linking monomers (II) and (III) under TV light.

In an example, a mass ratio of the monomer of formula (11) to the monomer of formula (III) that may be used to prepare an example of a bioadhesive polymer may be a ratio from 0:100 to 100:0, including, for example, 0:100, or 1:95, or 1:90, or 1:85, or 1:80, or 1:75, or 1:70, or 1:65, or 1:60, or 1:55, or 1:50, or 1:45, or 1:40, or 1:35, or 1:30, or 1:25, or 1:20, or 1:15, or 1:10, or 1:9, or 1:8, or 1:7, or 1:6, or 1:5, or 1:4, or 1:3, or 1:2, or 1:1, or 2:1, or 3:1, or 4:1, or 5:1, or 6:1, or 7:1, or 8:1, or 9:1, or 10:1, or 15:1, or 20:1, or 25:1, or 30:1, or 35:1, or 40:1, or 45:1, or 50:1, or 55:1, or 60:1, or 65:1, or 70:1, or 75:1, or 80:1, or 85:1, or 90:1, or 95:1, or 100:0; or a range formed from any two of the foregoing ratios; including any subranges therebetween.

In an example, a wavelength of UV light may be of a wavelength of from 200 nanometers to 600 nanometers, including, for example, 205 nanometers, or 210 nanometers, or 215 nanometers, or 220 nanometers, or 225 nanometers, or 230 nanometers, or 235 nanometers, or 240 nanometers, or 245 nanometers, or 250 nanometers, or 255 nanometers, or 260 nanometers, or 265 nanometers, or 270 nanometers, or 275 nanometers, or 280 nanometers, or 285 nanometers, or 290 nanometers, or 295 nanometers, or 300 nanometers, or 305 nanometers, or 310 nanometers, or 315 nanometers, or 320 nanometers, or 325 nanometers, or 330 nanometers, or 335 nanometers, or 340 nanometers, or 345 nanometers, or 350 nanometers, or 355 nanometers, or 360 nanometers, or 365 nanometers, or 370 nanometers, or 375 nanometers, or 380 nanometers, or 385 nanometers, or 390 nanometers, or 395 nanometers, or 400 nanometers, or 405 nanometers, or 410 nanometers, or 415 nanometers, or 420 nanometers, or 425 nanometers, or 430 nanometers, or 435 nanometers, or 440 nanometers, or 445 nanometers, or 450 nanometers, or 455 nanometers, or 460 nanometers, or 465 nanometers, or 470 nanometers, or 475 nanometers, or 480 nanometers, or 485 nanometers, or 490 nanometers, or 495 nanometers, or 500 nanometers, or 505 nanometers, or 510 nanometers, or 515 nanometers, or 520 nanometers, or 525 nanometers, or 530 nanometers, or 535 nanometers, or 540 nanometers, or 545 nanometers, or 550 nanometers, or 555 nanometers, or 560 nanometers, or 565 nanometers, or 570 nanometers, or 575 nanometers, or 580 nanometers, or 585 nanometers, or 590 nanometers, or 595 nanometers; or a range formed from any two of the foregoing wavelengths; including any subranges therebetween.

In an example, a temperature for annealing the crosslinked film may be a temperature of from about 60° C. to about 200° C., including, for example, about 65° C., or about 70° C., or about 75° C., or about 80° C., or about 85° C., or about 90° C., or about 95° C., or about 100° C., or about 105° C., or about 110° C., or about 115° C. or about 120° C., or about 125° C., or about 130° C., or about 135° C., or about 140° C., or about 145° C., or about 150° C., or about 155° C., or about 160° C., or about 165° C., or about 170° C., or about 175° C., or about 180° C., or about 185° C., or about 190° C., or about 195′ C; or a range formed from any two of the foregoing temperatures; including any subranges therebetween.

The compositions and processes described above may be better understood in connection with the following Examples. In addition, the following non-limiting examples are an illustration. The illustrated methods are applicable to other examples of stretchable light-emitting polymers of the present disclosure. The procedures described as general methods describe what is believed will be typically effective to prepare the compositions indicated. However, the person skilled in the art will appreciate that it may be necessary to vary the procedures for any given example of the present disclosure, for example, vary the order or steps and/or the chemical reagents used.

### EXAMPLES

### I. Materials and Methods

### A. Materials

The chemicals used herein, including tetra(ethylene glycol), acryloyl chloride, triethylamine, succinic anhydride, 4-dimethyaminopyridine (DMAP), N-hydroxysuccinimide (NHS), 2,5bis(trimethylstannyl)thiophene, trimethyl(phenyl)tin, bromobenzene, 2-hydroxy-2-methylpropiophenone, anhydrous dichloromethane (“DCM”), anhydrous chloroform, and anhydrous chlorobenzene were purchased from Sigma-Aldrich and used without further purification. Tetraethylene glycol dimethylacrylate was purchased from Polysciences inc. 1-Ethyl-3-(3-dimethylaminopropyl)carbodiimide hydrochloride (“EDC”) was purchased from Oakwood Chemical. 5,5′-Dibromo-3,3′-bis(2-(2-(2-methoxyethoxy)ethoxy)ethoxy)-2,2′-bithiophene was purchased from SunaTech Inc. SEBS was obtained from Asahi Kasei. The thermoplastic polyurethane was obtained from BASF.

### B. Characterizations

Microwave polymerization was conducted using a Biotage Initiator+. Nuclear magnetic resonance (“NMR”) spectra were recorded on a Bruker Avance HD console spectrometer (¹H 400 MHz, ¹³C 100 MHz) at 293 K. Chemical shifts are given in parts per million (“ppm”) with respect to tetramethylsilane (“TMS”) as an internal standard, and coupling constants (J) are given in Hertz (Hz). High-resolution mass spectra (“HR-MS”) were recorded on an Agilent 6530 LC Q-TOF mass spectrometer using electrospray ionization with fragmentation voltage set at 70 V and processed with an Agilent MassHunter Operating System. Number-average molecular weight (Mₙ), weight-average molecular weight (A), and polydispersity index (PDI) were evaluated by Tosoh EcoSEC size exclusion chromatography system (GPC) using DMF+0.01 M LiBr as eluent (50° C.) calibrated with polystyrene standards. The UV-Vis absorption spectra were recorded on a Shimadzu UV-3600 Plus UV-VIS-NIR spectrophotometer. Water contact angle measurement was done with a KRÖSS DSA100 drop shape analyzer. Differential Scanning Calorimetry (DSC) experiments were performed with a TA Instruments Discovery 2500 differential scanning calorimeter. Atomic force microscope (AFM) imaging was done with a Bruker Multimode 8 AFM. Scanning electron microscope (STEM) imaging was done with a FEI Quanta 650 FEG STEM. Depth-profiling X-ray photoelectron spectroscopy (XPS) was done with a Kratos AXIS Nova with a monochromatic A1 Kα X-ray source and a delay line detector (DLD) system with Ar1000+ with 10 keV to etch. Grazing-incidence X-ray diffraction (GIXD) was performed at the Advanced Photon Source at Argonne National Laboratory on beamline 8-ID-E.

### C. Semiconducting Film Fabrication

Glass substrates were treated with a n-octadecyltrimethoxysilane (“OTS”) layer on the surface. P(g2T-T) polymer was dissolved in chloroform with a concentration of 5 mg/mL. For non-adhesive semiconducting polymer films, the polymer solution was directly spin-coated on the OTS-treated glass substrate at a spin speed of 1000 r.p.m. for 1 minute in a nitrogen-filled glovebox. The polymer film was finally annealed at 110° C. for 5 minutes. For preparing the bioadhesive semiconductor precursor solution, a certain amount of well-dissolved p(g2T-T) solution (5 mg/mL) in chloroform was mixed with desired amounts of ACTEGCOOH or ACTEGNHS monomers according to Table 1, 0.5 weight % of 2-hydroxy-2-phenylpropiophenone (as the photoinitiator) and 0.5 weight % of tetraethylene glycol dimetharcylate (as the crosslinker) in chloroform. For preparing BASC polymer, a weight ratio of p(g2T-T) to ACTEGCOOH to ACTEGNHS is 1:20:20. The mixture was allowed to stir for 20 minutes at 60° C. before spin-coating. The polymer solution was spin-coated on the OTS-treated glass substrates at a spin speed of 1000 r.p.m. for 1 minute in a nitrogen-filled glovebox. The film was then photo-polymerized under 365-nanometer UV light for 5 minutes, followed by annealing at 110° C. for 5 minutes in a nitrogen-filled glovebox. For adhesion and mechanical characterizations of the semiconducting films, stretchable substrates were fabricated by dissolving TPU in THF at a concentration of 60 mg/mL and then drop-casting the solution on a clean glass substrate to obtain a uniform TPU film (thickness of about 70 μm) after complete evaporation of the solvent at room temperature. The semiconducting polymer precursor solution as spin-coated on the TPU substrates at a spin speed of 1,000 r.p.m. for 1 minute in a nitrogen-filled glovebox. The polymer film was then photocured under 365-nanometer UV light for 5 minutes, followed by annealing at 110° C. for 5 minutes in the glovebox. The TPU film may be peeled off the glass substrate.

### D. Organic Electrochemical Transistor (“OECT”) Fabrication for Characterization of Electrical Performance

First, a glass substrate was cleaned with acetone, isopropyl alcohol, and water, sequentially. Next, the source/drain gold electrodes (60-nanometer thick) were patterned via e-beam evaporation with a metal shadow mask. The channel length (L) and width (W) were 200 μm and 4 mm, respectively. The semiconducting polymer films were transferred onto the channel area using a PDMS stamp. An electrolyte of 0.1 M NaCl solution was dropped on top of the channel. The gate electrode was served by Ag/AgCl. The performance of the fabricated OECTs was measured using Keithley 4200 under an ambient environment. The transconductance gₘ was calculated based on the equation (1):

$${g}_{m} = \frac{\partial {I}_{d}}{\partial {V}_{g}} \qquad ( 1 )$$

wherein I_{d} is the drain current and V_{g} is the gate voltage.

### E. Mechanical Characterization

For rheology measurement, the adhesive semiconductor precursor solution was drop-casted on a clean glass substrate and was fully polymerized under 365-nanometer UV light in a nitrogen-filled glovebox. The samples were annealed at 110° C. for 10 minutes to fully remove the residue solvent. The final film was cut into a circular shape with a diameter of 10 millimeters and a thickness of about 0.8 millimeters. The rheology test was done with TA Instruments ARES-G2 shear rheometer at room temperature.

For adhesion tests, the semiconducting polymer films were prepared on TPU as described above. The TPU substrates were then cut into a rectangular shape with a length/width of 80 millimeters/6 millimeters. The semiconducting polymer occupied one end with an average length/width of 10 millimeters/6 millimeters.

The surfaces of synthetic materials including PDMS, TPU, glass, and gold were treated with primary amine groups according to literature procedures. See A. Inoue, et al., Strong adhesion of wet conducting polymers on diverse substances, 6 SCIENCE ADVANCES caay5394 (2020), the entirety of which is incorporated by reference herein.

The biological tissues were purchased from local markets. Generally, the biological tissues were cut into rectangular pieces and rinsed with 0.1×PBS solution and pre-dried gently with Kimwipe to remove excess water on the surface. The biological tissues were fixed to a glass substrate at one end with Kapton tape. The bioadhesive polymers on TPU substrates were adhered to the bio-tissue surface by gently pressing of ~5 kPa for 1 minute. All the samples were stored in a sealed bag at 4-8° C. for 2 hours before the mechanical test.

The interfacial toughness was tested by the 180° peel test with a Zwick-Roell zwickiLine Z0.5 materials testing instrument. All tests were conducted with a constant peeling speed of 0.5%/s. Interfacial toughness was calculated from the plateau force and the width of the adhesion area following the corresponding ASTM standard. The shear strength was tested by the lap-shear test with the Zwick-Roell zwickiLine Z0.5 materials testing instrument. The tensile strength was tested by the tensile test with the Zwick-Roell zwickiLine Z0.5 materials testing instrument. All tests were conducted with a constant tensile speed of 0.5%/s. Shear strength was calculated by dividing the maximum force by the adhesion area following the corresponding ASTM standard.

### F. In Vivo Biocompatibility

Male C57BL/6 mice (aged 8 weeks) were purchased from Charles River Laboratory. All of the animal experiments performed the research were approved by the Institutional Animal Care and Use Committee of the University of Chicago.

The elastomer SEBS-1221 substrate with a thickness of 1 millimeter were prepared by drop-casting the SEBS solution in toluene onto a clean glass substrate. The adhesive polymer samples were prepared by spin-coating adhesive precursor solution in chloroform on oxygen plasma treated SEBS substrates at a spin speed of 1,000 r.p.m. for 1 minute in a nitrogen-filled glovebox. The polymer films were then photocured under 365 nm UV light for 5 minutes, followed by annealing at 110° C. for 5 minutes in a nitrogen-filled glovebox. The other side of SEBS substrate was coated with the adhesive polymer in the same way. The adhesive polymer-coated SEBS substrates were punched into circular disks with a diameter of 6 millimeters with biopsy. Before implantation, all of the disks were sterilized with 70% ethanol solution and UV light for 20 minutes each. Anesthesia was maintained using a nose cone. The back hair was removed. The subcutaneous space was accessed by a 1-2 centimeter skin incision per implant in the center of the animal's back. To create space for implant placement, blunt dissection was performed from the incision towards the animal's shoulder blades. The sample was placed in the subcutaneous pocket created above the incision (n=5). The incision was closed with interrupted sutures. After one month after the implantation, the animals were killed by CO₂ inhalation. The implanted samples were excised and collected for biocompatibility analysis.

### G. Histological Analysis (Trichrome Staining)

The mice skin samples were harvested at scheduled end point and incubated in 2% PFA for 2 days at 4° C. The fixed skin samples were submitted to paraffin embedding process and sectioned at 5 μm thickness. Trichrome staining was conducted by Human Tissue Resource Center, the University of Chicago. The slides were imaged by EVOS FL Auto (Life Technologies).

### H. Immunofluorescence Analysis

The paraffin embedded skin samples were sectioned at μm thickness, and the slides were prepared with deparaffination process. The slides were incubated in perm/blocking buffer (0.3% Triton X-100, 1% BSA in PBS) for 3 hours at room temperature. The slides were washed using 1×PBS three times and incubated in primary antibody solution (0.1% tween 20 in PBS) for overnight at 4° C. The primary antibodies information: Anti-alpha smooth muscle Actin antibody (EPR5368, abcam) and CD68 Monoclonal Antibody (FA-11, Invitrogen). The slides were washed using 1×PBS three times and incubated in secondary antibody solution (0.1% tween 20 in PBS) for 3 hours at room temperature. Secondary antibody information: Donkey anti-Rat IgG (H+L) Alexa Fluro™ 594 Secondary Antibody and Goat anti-Rabbit IgG Alexa Fluor™ 647 Secondary Antibody (Invitrogen). Then, the slides were washed using 1×PBS three times and stained using DAPI. The stained skin slides were covered with mounting solution and dried overnight in a dark place. The slides were imaged by Olympus confocal microscopy system.

### I. Fabrication of Fully-Bioadhesive OECT Sensors

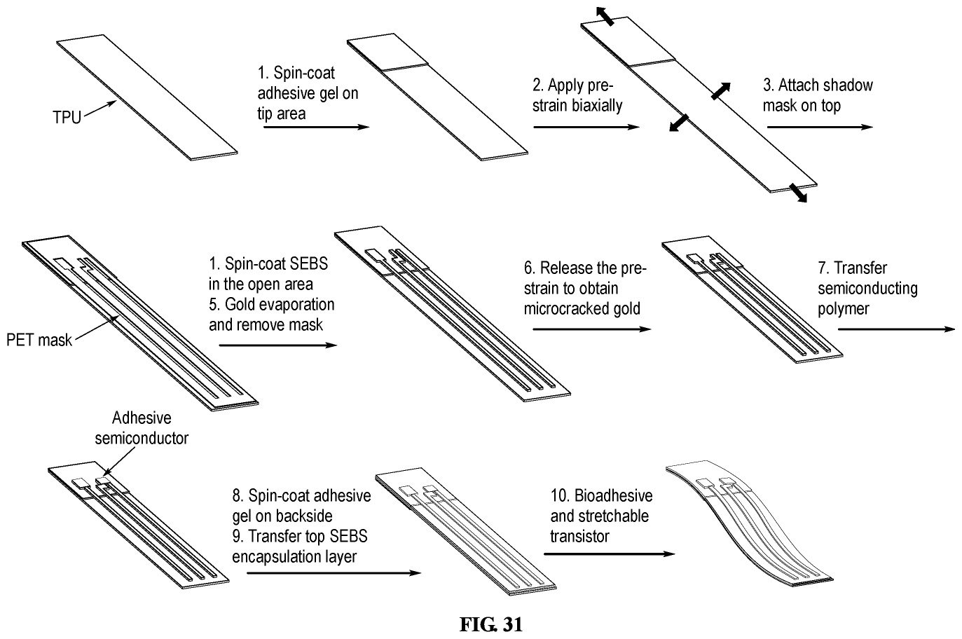

The process for fabrication of a fully bioadhesive OECT sensor is illustrated in FIG. 31. BAP adhesive precursors in chloroform were spin-coated on the tip area of oxygen plasma treated TPU substrates followed by curing at 365-nm light for 5 minutes and annealing at 110° C. for 5 minutes in a nitrogen-filled glovebox. The prepared substrates were stretched biaxially (stretched along one major direction at 80% strain, and along the other direction for around 30% strain) and fixed to a glass substrate. Then a PET shadow mask was attached to each substrate with openings for gate, source, and drain electrodes sitting on the adhesive area. SEBS 1052 solution in toluene with a concentration of 10 mg/mL was spin-coated on the open channel as the bottom encapsulation layer. The titanium/gold electrodes were fabricated through e-beam evaporation to achieve a thickness of 5 nanometers/80 nanometers, respectively. Then the mask was carefully removed. The fixed substrate was slowly released to the original shape of the fixed substrate so microcracked gold electrodes were obtained. The BASC films were transferred to the channel area and the gate area to serve as both the channel and gate materials. The device was flipped and the BAP adhesive monomer precursors in chloroform were spin-coated on the backside of the tip area on the TPU substrate followed by curing at 365-nanometer UV light for 5 minutes and annealing at 110° C. for 5 minutes in a nitrogen-filled glovebox. Thin SEBS 1052 films (~572 nanometers) were transferred with a PDMS stamp to encapsulate the exposed gold electrodes. The completed device was released from the glass substrate.

### J. Fabrication of the Non-Bioadhesive OECT Sensor

A TPU substrate was stretched biaxially (stretched along one major direction at 80% strain, and along the other direction for around 30% strain) and fixed to a glass substrate. A PET shadow mask was attached to the substrate. Then SEBS 1052 solution in toluene with a concentration of 10 mg/mL was spin-coated on the open channel as the bottom encapsulation layer. The titanium/gold electrodes were fabricated through an e-beam evaporator with a thickness of 5 nanometers/80 nanometers, respectively. Then the mask was carefully removed. The fixed substrate was slowly released to the original shape of the fixed substrate so microcracked gold electrodes were obtained. Neat semiconducting polymer p(g2T-T) films were transferred to the channel area and the gate area to serve as both the channel and the gate materials. Thin SEBS 1052 films (~570 nanometers) were transferred with a PDMS stamp to encapsulate the exposed gold electrodes. The device was released from the glass substrate.

### K. Ex Vivo ECG Measurement

Isolated rat hearts were prepared following a previously described method. See A. Prominski, et al., Porosity-based heterojunctions enable leadless optoelectronic modulation of tissues, 21 NAT. MATER. 647 (2022), the entirety of which is incorporated by reference herein. An adult rat (male, 300-400 g body weight) was heparinized and anesthetized using open-drop exposure of isoflurane in a bell jar configuration. The heart was removed and placed in ice-cold HBSS buffer, and the aorta was cannulated in preparation for use in a Langendorff setup. Oxygenated HEPES-buffered Tyrode's solution was perfused through the cannulated aorta after passing through a heating coil and bubble trap (Radnoti). The heart was placed in a water-jacketed beaker (Fisher Scientific) to maintain a temperature of 37° C. The perfusion pressure was maintained at 80-100 mmHg. The sinoatrial node along with the atria were removed to lower the atrioventricular node pace. The perfusion and left ventricular pressure were monitored using a BP-100 probe (iWorx) connected to the perfusion line and a water-filled balloon (Radnoti) inserted into the LV, respectively. For ECG recordings, a fully-bioadhesive (or non-bioadhesive) OECT sensor was positioned on the ventricular wall and the source-drain voltage was powered by a Keithley 2450 SoruceMeter. Gentle pressure was applied on the back of the OECT device for 20 seconds to ensure adhesion. The output signals were connected to a C-ISO-256 preamplifier (iWorx). All signals (perfusion, left ventricular pressure, and ECG) were amplified using an IA-400D amplifier (iWorx) and interfaced with a computer using a Digitate 1550 digitizer with Clampex software (Molecular Devices).

### II. Materials Syntheses

A. Scheme for Synthetic Pathway to 2,5-dioxopyrrolidin-1-yl 13-oxo-3,6,9,12-tetraoxapentadec-14-en-1-yl succinate (Compound 3, Monomer of formula (III)).

The following Scheme A was followed to obtain Compound 3 (Monomer of formula (III)) as an ultimate product, and 3,17-dioxo-4,7,10,13,16-pentaoxaicos-1-en-20-oic acid (Compound 2, Monomer of formula (II)) as an intermediate:

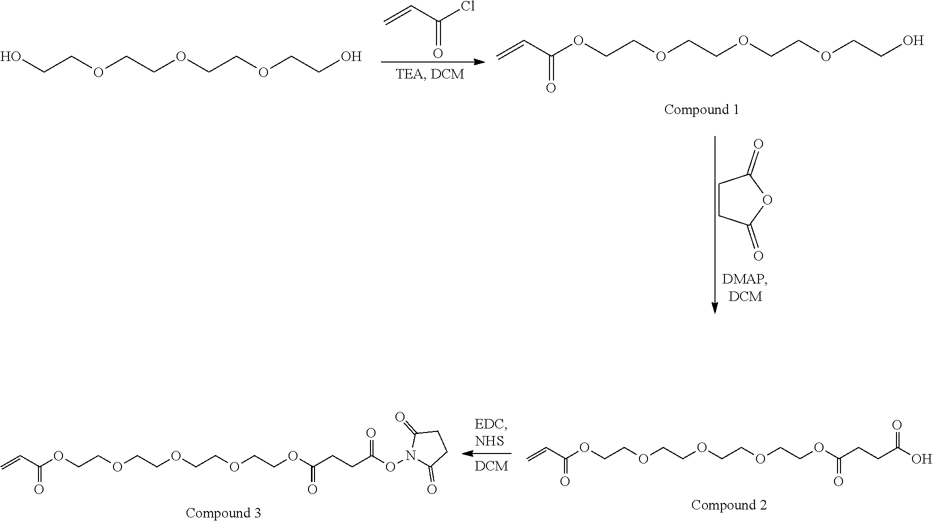

### 1. Synthesis of 2-(2-(2-(2-hydroxyethoxy) ethoxy) ethoxy)ethyl Acrylate (Compound 1)

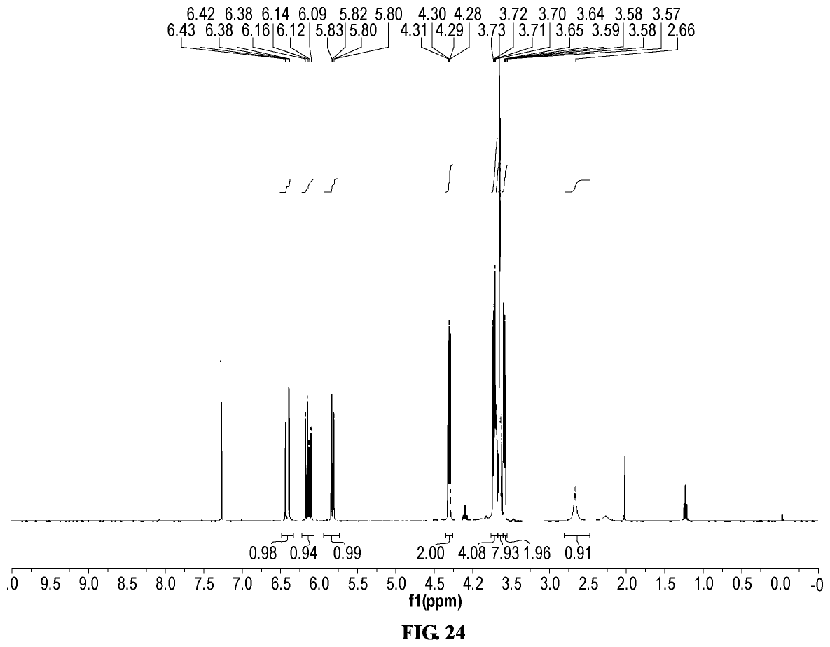

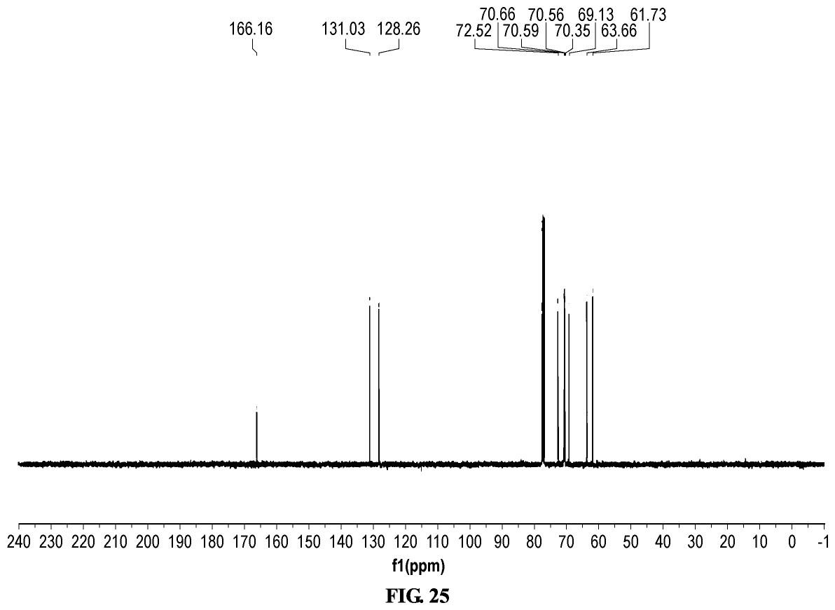

To a round bottom flask (“RBF”) equipped with a stirring bar, tetra(ethylene glycol) (103 mmol, 20 g) and triethylamine (41.2 mmol, 4.2 g) were added to 30 milliliters of anhydrous dichloromethane (“DCM”) under nitrogen atmosphere at approximately 0° C. Acryloyl chloride (20.6 mmol, 1.86 g) was added dropwise under stirring. Then the mixture was stirred at room temperature (“r.t.”) overnight, after which the reaction mixture was filtered to remove solid, and the solution washed with water. The mixture was extracted with DCM. The solved was removed using rotary evaporation and purified by column chromatography (silica gel, EtOAc/MeOH=95:5, v:v). 2-(2-(2-(2-Hydroxyethoxy)ethoxy)ethoxy)ethyl acrylate (Compound 1) was isolated as a colorless oil (4.8, 94% yield). ¹H NMR (400 MHz, CDCl₃, FIG. 24) δ 6.40 (dd, J=17.3, 1.4 Hz, 1H), 6.13 (dd, J=17.3, 10.4 Hz, 1H), 5.81 (dd, J=10.4, 1.4 Hz, 1H), 4.30 (dd, J=5.5, 4.2 Hz, 2H), 3.76-3.67 (m, 4H), 3.67-3.61 (m, 8H), 3.58 (dd, J=5.3, 3.8 Hz, 2H), 2.66 (s, 1H); ¹³C NMR (101 MHz, CDCl₃, FIG. 25) δ 166.16, 131.03, 128.26, 72.52, 70.66, 70.59, 70.55, 70.35, 69.13, 63.65, 61.73. HRMS (ESI) calculated for C₁₁H₂₁O₆ [M+H]⁺: 249.1333. found 249.1334.

### 2. Synthesis of 3,17-dioxo-4,7,10,13,16-pentaoxaicos-1-en-20-oic Acid (Compound 2, Monomer of Formula (II))

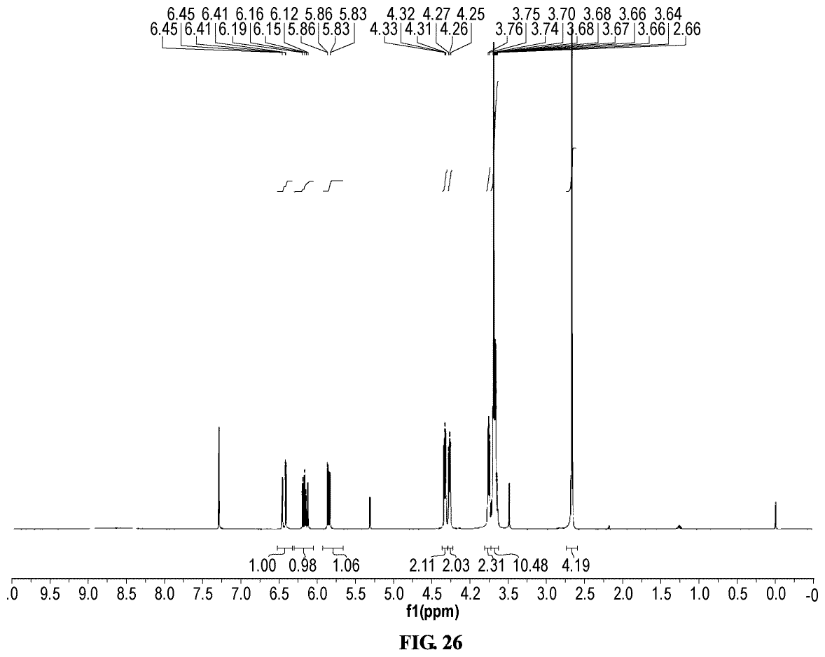

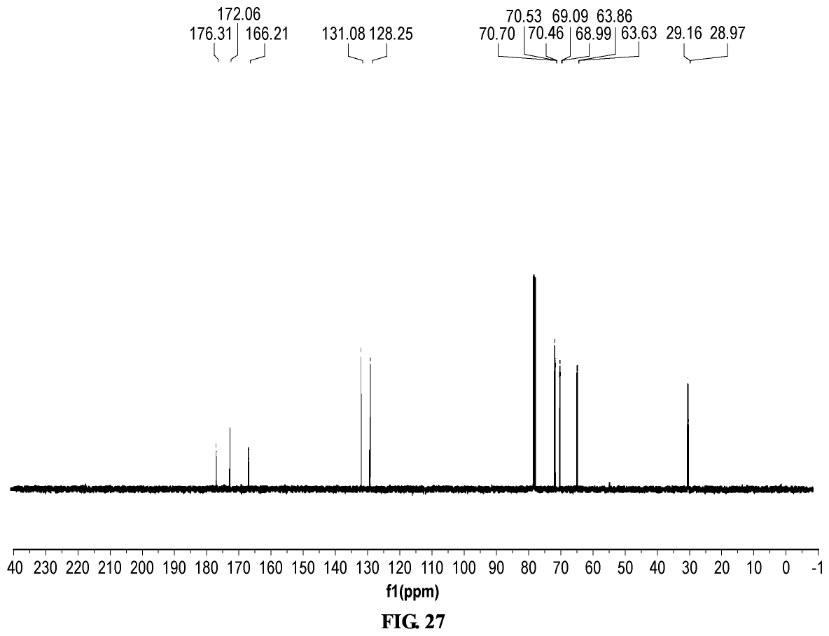

To a RBF equipped with a stirring bar, Compound 1 (16 mmol, 4 g), succinic anhydride (32 mmol, 3.2 g), and N,N-dimethylaminopyridine (“DMAP,” 1.1 mmol, 138 mg) were added to 40 milliliters of anhydrous DCM under nitrogen atmosphere. The mixture was stirred at room temperature for 12 hours, after which the solution was washed with 1 M aqueous HCl and brine, successively. The mixture was extracted with DCM. The solvent was removed using rotary evaporation and purified by column chromatography (silica gel, EtOAc/MeOH=95:5, v:v). 3,17-Dioxo-4,7,10,13,16-pentaoxaicos-1-en-20-oic acid (Compound 2) was isolated as a colorless oil (3.9 g, 70% yield). ¹H NMR (400 MHz, CDCl₃, FIG. 26) δ 6.43 (dd, J=17.3, 1.4 Hz, 1H), 6.15 (dd, J=17.3, 10.4 Hz, 1H), 5.84 (dd, J=10.4, 1.4 Hz, 1H), 4.31 (dd, J=5.5, 4.2 Hz, 2H), 4.28 (dd, J=5.5, 4.1 Hz, 2H), 3.78-3.73 (m, 2H), 3.73-3.69 (m, 2H), 3.69-3.62 (m, 8H), 2.96 (t, J=7.1 Hz, 2H), 2.84 (s, 4H), 2.78 (t, J=7.0 Hz, 2H); ¹³C NMR (101 MHz, CDCl₃, FIG. 27) δ 176.31, 172.06, 166.21, 131.08, 128.25, 70.70, 70.53, 70.46, 69.09, 68.99, 63.86, 63.63, 29.16, 28.97. HRMS (ESI) calculated for C₁₅H₂₅O₉ [M+H]⁺: 349.1494. found 349.1495.

### 3. Synthesis of 2,5-dioxopyrrolidin-1-yl (13-oxo-3,6,9,12-tetraoxapentadec-14-en-1-yl) succinate (Compound 3, Monomer of Formula (III))

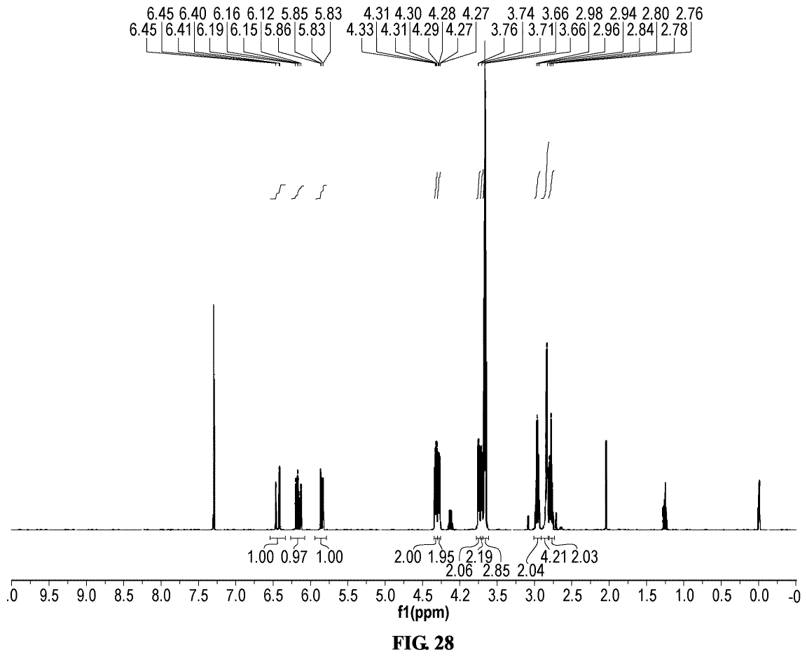

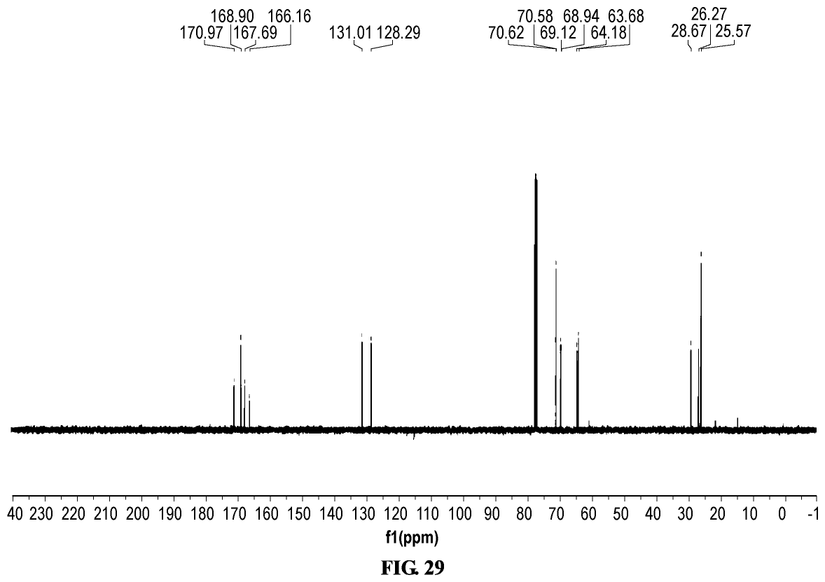

To a RBF equipped with a stirring bar, Compound 2 (5.7 mmol, 2 g) and N-hydroxysuccinimide (“NHS,” 6.3 mmol, 0.73 g) were added to 40 milliliters of anhydrous DCM under nitrogen atmosphere. The mixture was stirred at 0° C. for 30 minutes, then EDC (6.3 mmol, 0.98 g) in DCM was added to the solution dropwise. The reaction was stirred at room temperature for 12 hours, after which, the solution was washed with brine. The mixture was extracted with DCM. The solvent was removed using rotary evaporation and purified by column chromatography (silica gel, EtOAc). 2,5-Dioxopyrrolidin-1-yl (13-oxo-3,6,9,12-tetraoxapentadec-14-en-1-yl) succinate (Compound 3) was isolated as a colorless oil (1.9 g, 75% yield). ¹H NMR (400 MHz, CDCl₃, FIG. 28) δ 6.43 (dd, J=17.3, 1.3 Hz, 1H), 6.15 (dd, J=17.3, 10.4 Hz, 1H, 5.85 (dd, J=10.4, 1.3 Hz, 1H), 4.36-4.29 (m, 2H), 4.29-4.23 (m, 2H), 3.80-3.73 (m, 2H), 3.73-3.63 (m, 10H), 2.66 (s, 4H); ¹³C NMR (101 MHz, CDCl₃, FIG. 29) δ 170.97, 168.90, 167.69, 166.16, 131.01, 128.29, 70.62, 70.58, 69.12, 68.94, 64.18, 63.68, 28.67, 26.27, 25.57. HRMS (ESI) calculated for C₁₉H₂₈NO₁₁ [M+H]⁺: 446.1657. found 446.1647.

### B. Synthesis of p(g2T-T) (Formula (IV))

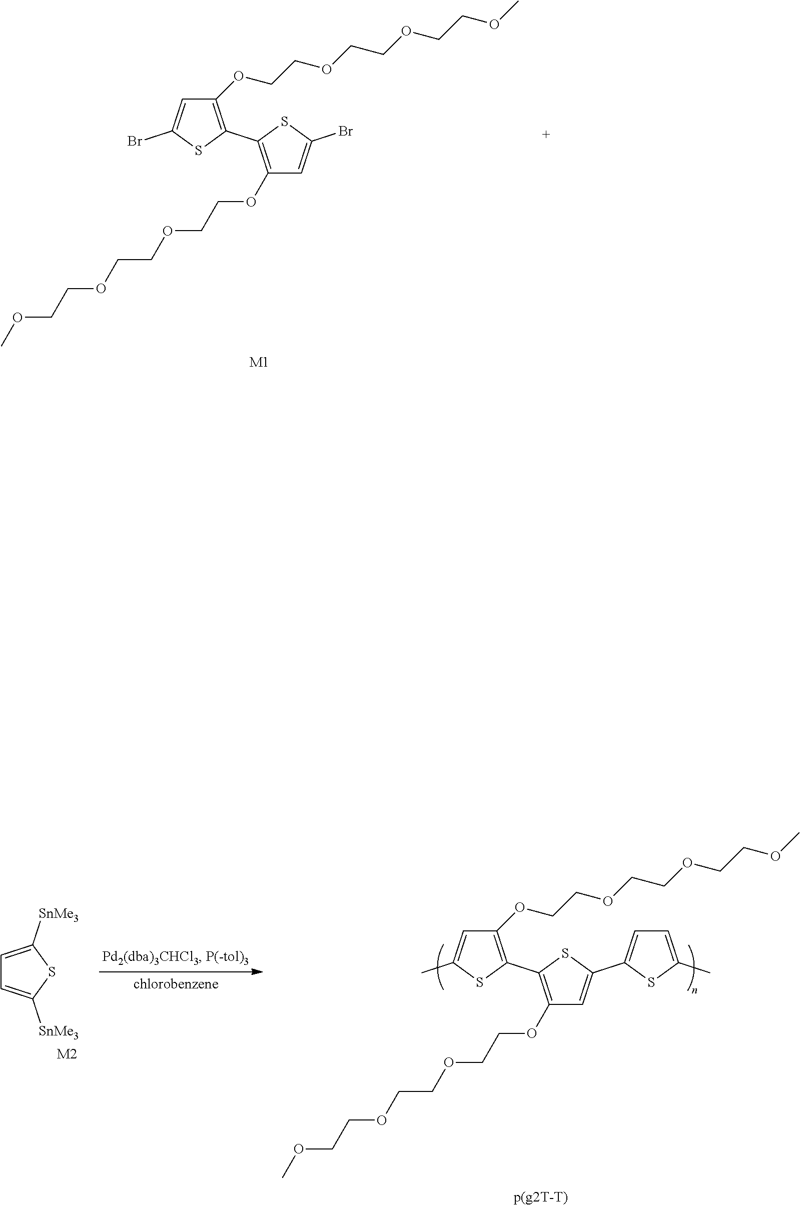

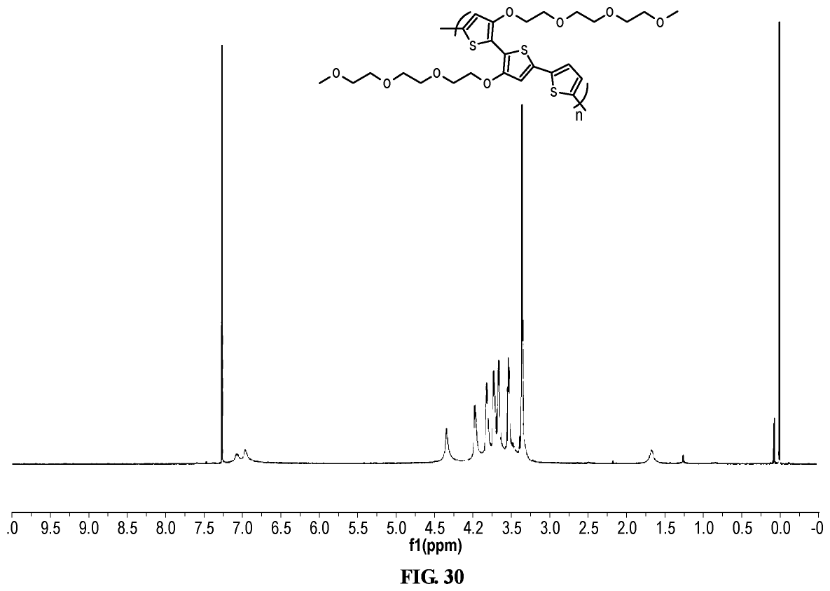

To a mixture of 5,5′-dibromo-3,3′-bis(2-(2-(2-methoxyethoxy) ethoxy) ethoxy)-2,2′-bithiophene (M1, 100 mg, 0.155 mmol, 1.0 equiv.), 2.5-bis(trimethylstanyl)thiophene (M2, 63.8 mg, 0.155 mmol, 1.0 equiv.), Pd₂(dba)₃CHCl₃ (3.2 mg, 0.0031 mmol, 0.02 equiv.), and P(o-tol)₃ (3.8 mg, 0.0124 mmol, 0.08 equiv.) was added 2 mL of chlorobenzene in a nitrogen-filled glovebox. The reaction vial was sealed and submitted to a microwave reactor with the following temperature profile: 2 minutes at 80° C. and 5 minutes at 100° C. After the reaction was cooled down, 10 mol % of trimethyl(phenyl) stannane was added, and the crude polymer solution was heated again for 2 minutes at 80° C. To complete the end-capping of the polymer, 10 mol % of bromobenzene was added, and the reaction vessel was submitted again to microwave heating (2 minutes at 80° C.). The crude polymer was then precipitated into methanol, filtered, loaded to a Soxhlet thimble, and washed successively with hexane and acetone (each for 24 hours). The polymer was collected from the thimble with chloroform. The solvent was then removed using rotary evaporation and the polymer was obtained as a blue solid. ¹H NMR (400 MHz, CDCl₃) of p(g2T-T) is illustrated in FIG. 30. The p(g2T-T) has a Ma of 36 kDa, a Mn of 63 kDa, and a polydispersity index (PDI) of 1.7.

### III. Preparation of BASC Films

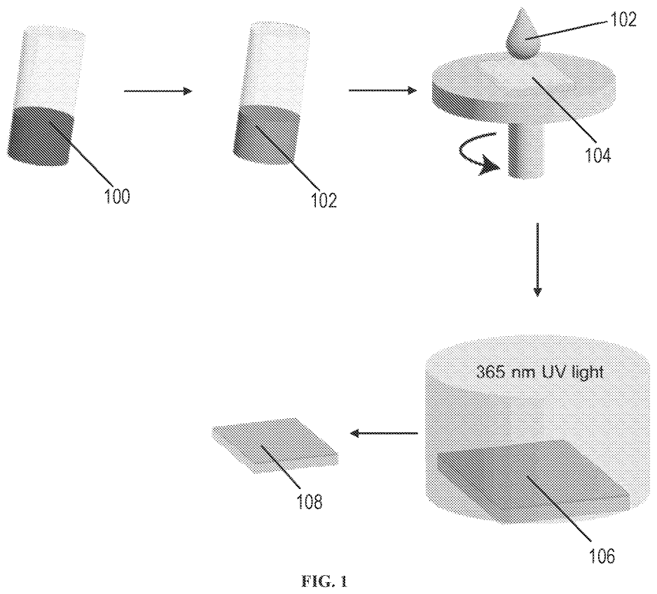

A schematic demonstrating the preparation of an example of a BASC film 100 of the present disclosure is illustrated in FIG. 1. The semiconducting polymer p(g2T-T) was dissolved in chloroform with stirring at 60° C. to prepare a solution 100. The BAP precursor solution including crosslinker (for example, tetraethylene glycol dimethacrylate), photoinitiator (for example, 2-hydroxy-2-phenylpropiophenone), and the appropriate amount of adhesive monomers of formulae (II) and (III), according to Table 1 was added to the p(g2T-T) solution and mixed well under stirring to prepare a solution 102.

TABLE 1
Summary of mass ratios of experimental adhesive
polymer compositions

| | | ACTEGCOOH | ACTEGNHS |
|---|---|---|---|
| | p | (Monomer of | (Monomer of |
| | (g2T-T) | formula (II)) | formula (III)) |
| BASC | 1 | 20 | 20 |
| BASC-COOH | 1 | 40 | 0 |
| BASC-NHS | 1 | 0 | 40 |
| BAP | 0 | 20 | 20 |
| BAP-COOH | 0 | 40 | 0 |
| BAP-NHS | 0 | 0 | 40 |

The solution 102 was spin-coated onto the substrate 104 (for example, off-the-shelf substrate, thermoplastic polyurethane (“TPU”)) in a nitrogen gas-filled glovebox. The film was subjected to 365-nanometer ultraviolet light for 5 minutes to polymerize the adhesive network in a nitrogen gas-filled glovebox into a crosslinked film 106. The crosslinked film 106 was annealed at 110° C. for 5 minutes to complete the BASC film 108 preparation in the glovebox. The typical film thickness was a few micrometers.

### IV. Analysis

### A. BASC Film Water Absorption and Swelling Behavior

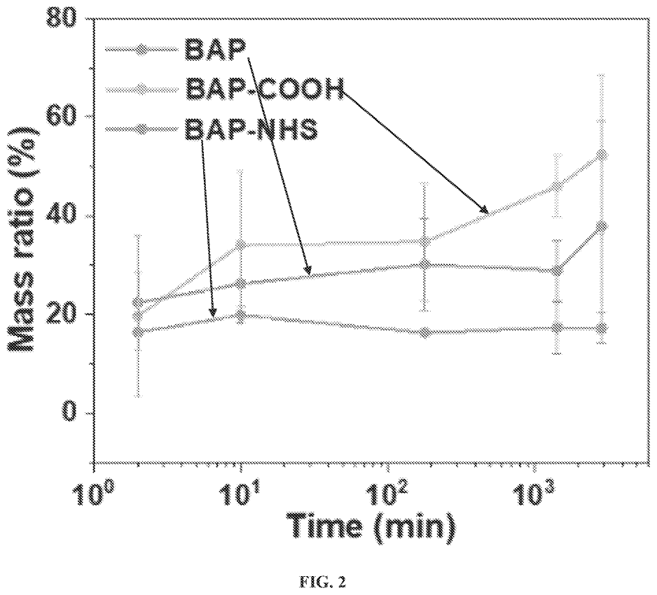

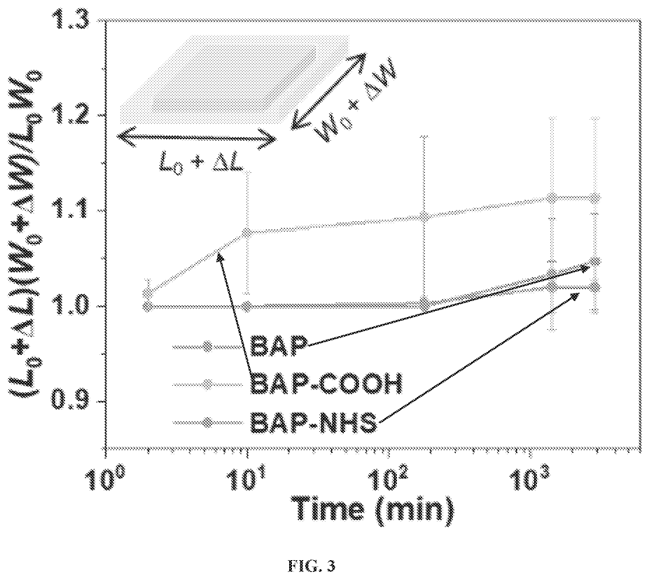

When a BASC film of the present disclosure contacts a surface of a biological tissue, the BAP of the BASC film may absorb and remove water on the tissue surface. After soaking into phosphate-buffered saline (“PBS”) solution, the mass of the BAP may increase quickly by ~20% from rapid water absorption, which is followed by gradual absorption over a subsequent 24 hours, as illustrated in FIG. 2. The volumetric swelling demonstrates a lateral expansion ratio of about 1.05, as illustrated in FIG. 3. By comparison, a BAP including a 1:1 mass ratio of monomer of formula (II) and monomer of formula (III) (such as “BAP,” Table 1) may moderately absorb water and swell, which may be between the level of water absorption and swelling of a BAP including only monomer of formula (II) (such as “BAP-COOH,” Table 1) and a BAP including only monomer of formula (III) (such as “BAP-NHS,” Table 1). The water absorption behaviors of a BAP including monomer of formula (II), a BAP including monomer of formula (III), and a BAP including monomers of formulae (II) and (III) are all much milder than the water absorption behaviors of poly(acrylic acid). The moderate water absorption for a BAP including monomers of formulae (II) and (III) is beneficial and advantageous for the stability of electrical performance from BASC films.

### B. BASC Film Adhesion Behavior

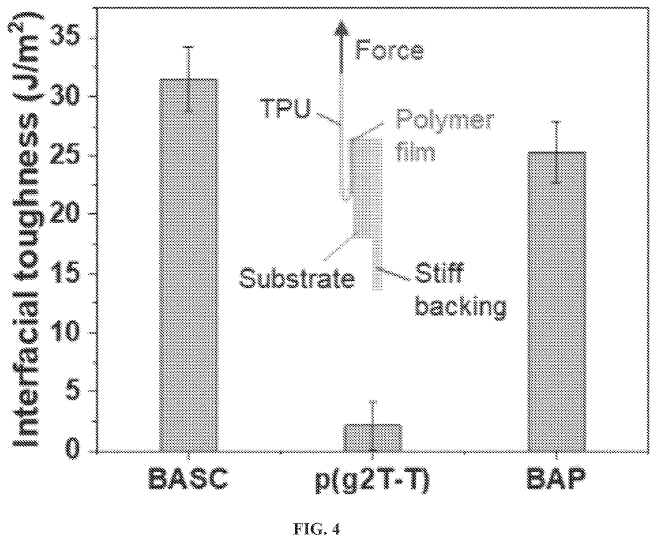

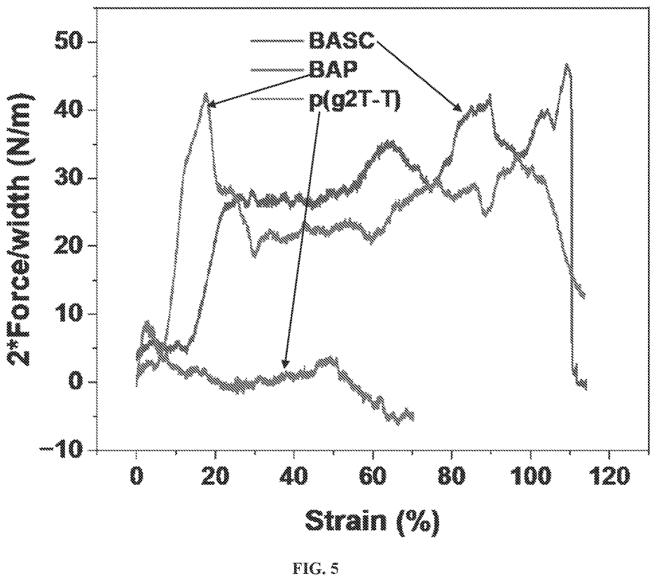

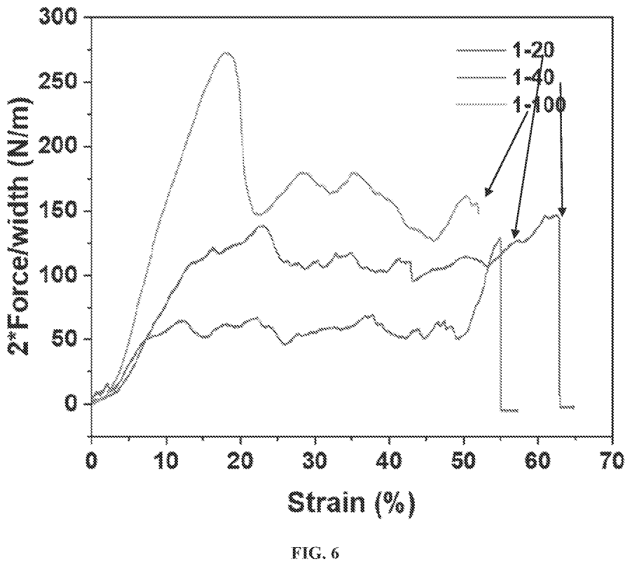

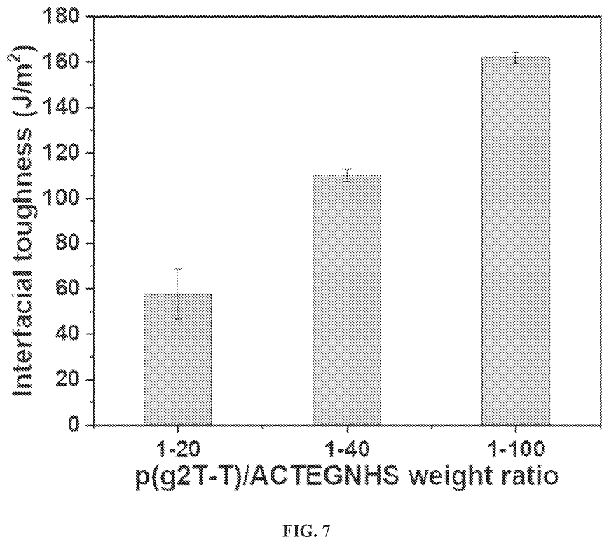

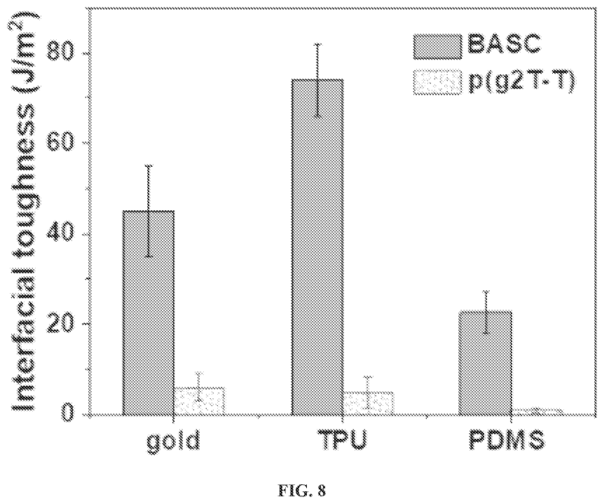

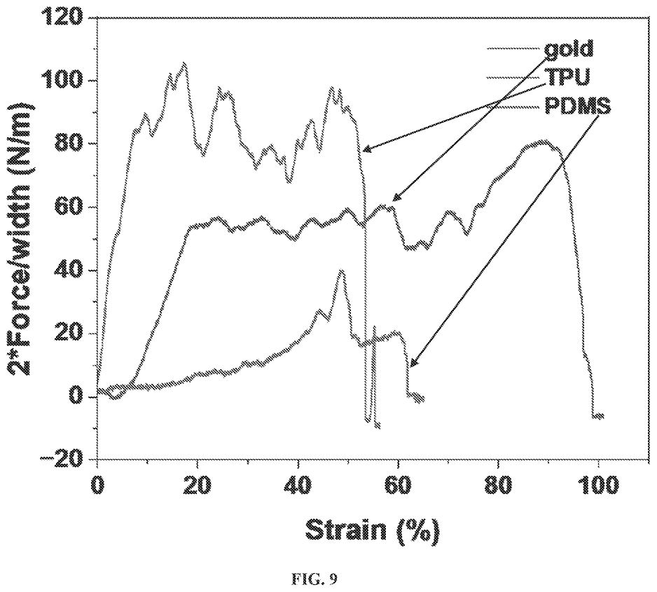

180-Degree peel, shear, and tensile tests on various synthetic materials and biological tissues were performed. First, BASC films supported on TPU substrates were held to the different surfaces with gentle pressure of about 5 kPa for 1 minute. On amine-treated glass surfaces, which may form covalent interactions with the 2,5-dioxopyrrolidin-1-yl ester moiety of the BASC films, the BASC films demonstrate much stronger and tougher adhesion (up to 15 times greater) than neat p(g2T-T) films, and adhesion strength and toughness comparable to BAP films, as illustrated in FIGS. 4-5. Tests of BASC films with other blending mass ratios of p(g2T-T) to monomer of formula (III) demonstrate the general trend of higher adhesion from higher amounts of BAP in the film, as illustrated in FIGS. 6-7. On various different synthetic surfaces, including gold, TPU, and polydimethylsiloxane (“PDMS”), BASC films form much stronger adhesion than neat p(g2T-T) films, as illustrated in FIGS. 8 and 9.

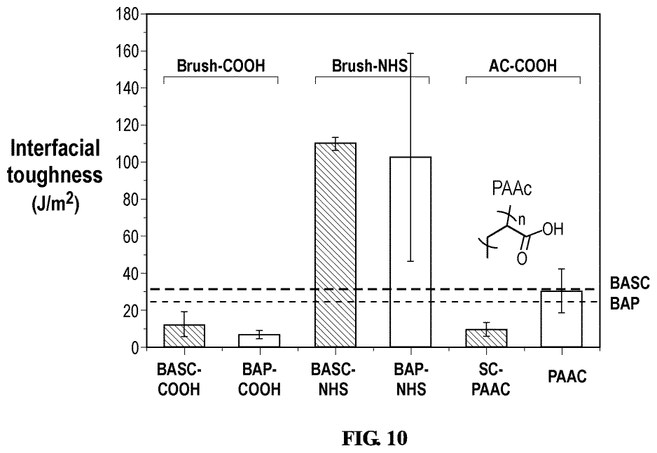

BAP including a 1:1 mass ratio of monomers of formulae (II) and (III) was compared with three polymers with the same backbone but different side chains: BAP-COOH, BAP-NHS, and regular polyacrylic acid (“PAAc”). BAP including a 1:1 mass ratio of monomers of formula (II) and (III) were also compared with the three blended semiconducting films produced from blending each of BAP, BAP-COOH, BAP-NHS, and PAAc with p(g2T-T) in a mass ratio of 1:40, which are BASC, BASC-COOH, BASC-NHS, and SC-PAAc, respectively. By testing on aine-functionalized glass surfaces, it was observed that among the three types of BAPs and resulting BASC films, higher adhesion was achieved with higher amounts of 2,5-dioxopyrrolidin-1-yl ester moiety, demonstrating that adhesion was mainly provided by the 2,5-dioxopyrrolidin-1-yl ester moiety. Each of the three BASC films built from each of BAP, BAP-COOH, and BAP-NHS, respectively, retained similar adhesion properties to the corresponding BAPs, as illustrated in FIG. 10.

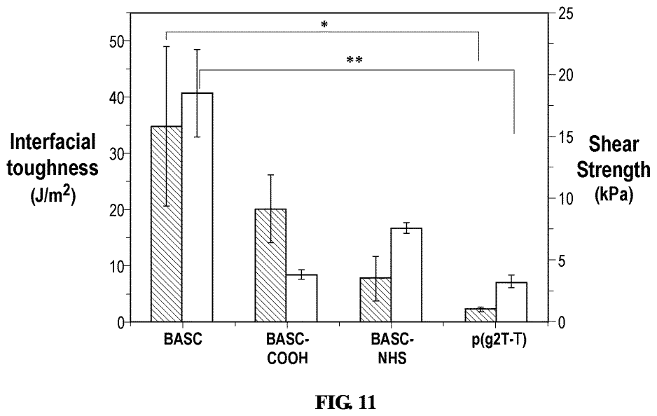

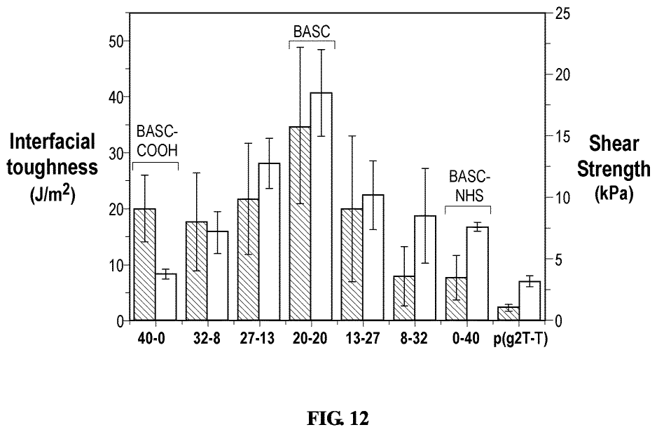

Adhesion performance of BASC films of the present disclosure on wet tissue surfaces was evaluated. As illustrated in FIG. 11 for porcine muscle surfaces, BASC films achieved an interfacial toughness of ~35 J/m² and a shear strength of ~18 kPa, which are a 10-fold increase over neat p(g2T-T) films. The adhesion properties of BASC films including monomers of formulae (II) and (III) in equal mass ratios were found to be higher than BASC-COOH or BASC-NHS films, and higher than BASC films including unequal mass ratios of formulae (II) and (III) as illustrated in FIG. 12. The side-chain data for tissue adhesion was different from the data on dry amine-glass surfaces, demonstrating the importance of hydrophilic COOH groups for absorbing water in establishing adhesion on wet tissue surfaces. The BASC films of the present disclosure may be applied to various wet tissues with high interfacial toughness and high shear strength relative to neat p(g2T-T) films. Examples of wet tissues may include the spleen, heart, and skin of a mammal.

### C. BASC Film Electrical Performance

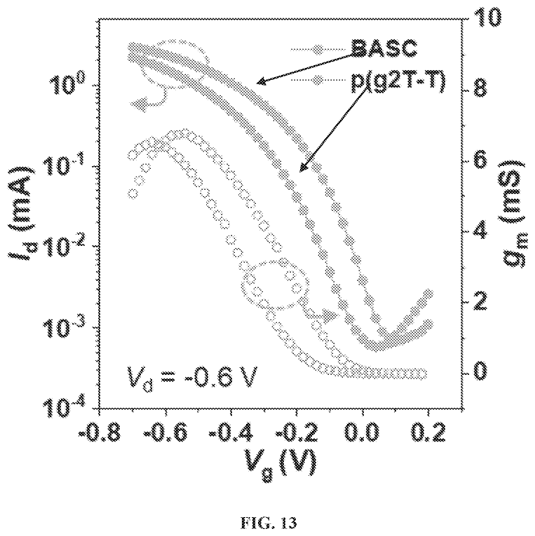

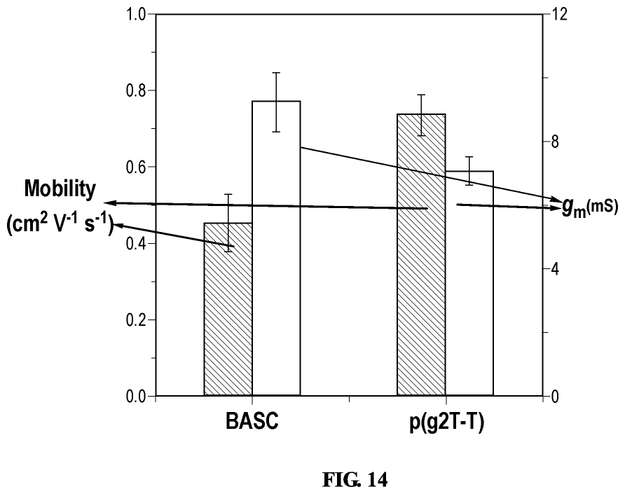

The electrical performance of BASC films was characterized in OECT devices with gold as the source/drain electrodes, NaCl (0.1 M) aqueous electrolyte, and Ag/AgCl reference gate. The OECT's transfer curve with an on/off ratio of 104 demonstrates ideal semiconducting performance from the BASC film, as illustrated in FIG. 13, which is on par with the performance of neat p(2gT-T) film. Through the constant gate current method, the obtained charge-carrier mobility of the BASC film was nearly 0.5 cm²·V⁻¹·s⁻¹, which was only a ~⅓ decrease from the charge-carrier mobility of the neat p(2gT-T) film, as illustrated in FIG. 14. The comparable charge-carrier mobility of the BASC film was the result of the percolated charge-transport pathway formed by the p(g2T-T) phase in the BASC film. On the device level, the maximum transconductance (gₘ) of the BASC film demonstrates a slight increase compared to the neat p(g2T-T) film, which may be due to an increased thickness (1.9 μm) of the BASC film relative to the neat p(g2T-T) film (35 nm). The measurement of the OECT response speed of the semiconducting films demonstrates that the increased thickness of the BASC films of the present disclosure does not result in a slower response to the gating compared to the neat p(g2T-T) film, as ions may transport very efficiently in the blended BAP.

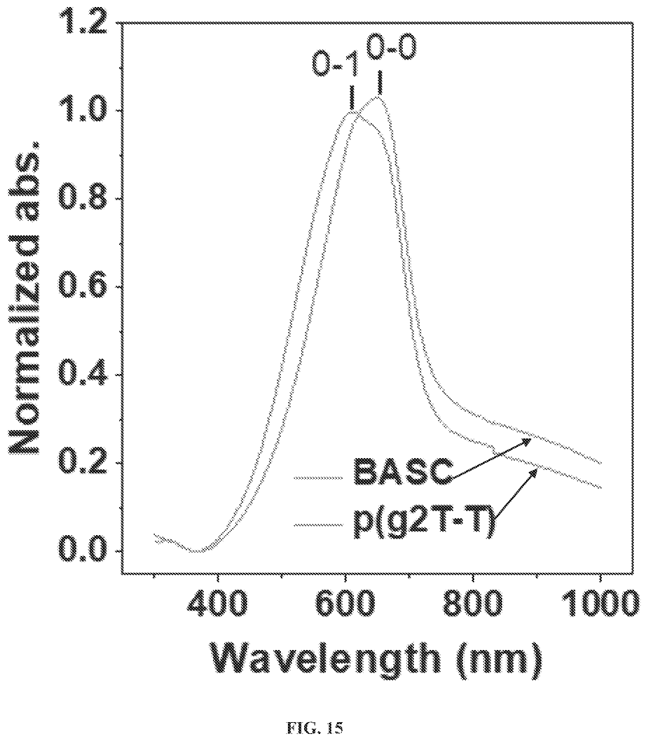

Grazing incidence X-ray diffraction (“GIXD)”) and UV-Vis spectroscopy were performed on the BASC films to evaluate interchain packing morphology of the p(g2T-T) phase in the film. The GIXD results revealed that blending with the BAP almost completely suppressed the long-range crystallization, which may decrease the modulus of the p(g2T-T) phase. The UV-Vis absorption spectroscopies illustrate that the p(g2T-T) phase in the BASC film actually has a higher level of short-range aggregation than the neat p(g2T-T) film, as represented by the ratios between 0-0 and 0-1 optical transition peaks, as illustrated in FIG. 15.

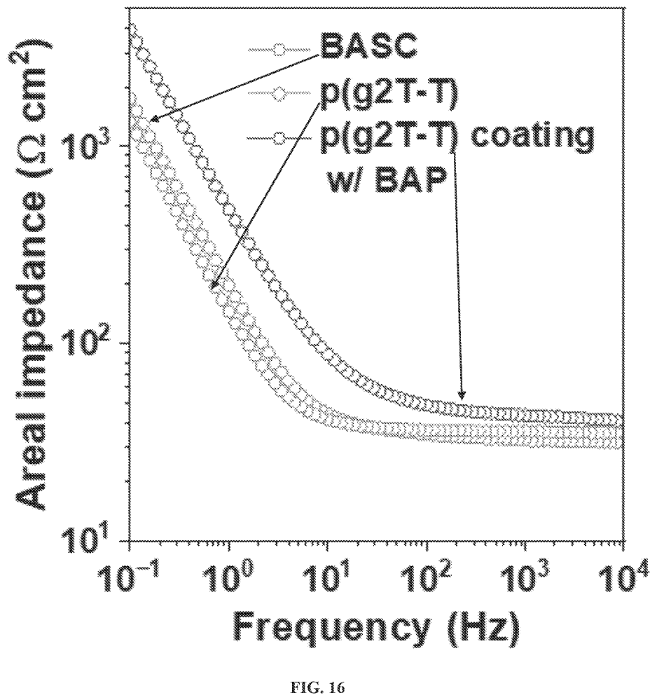

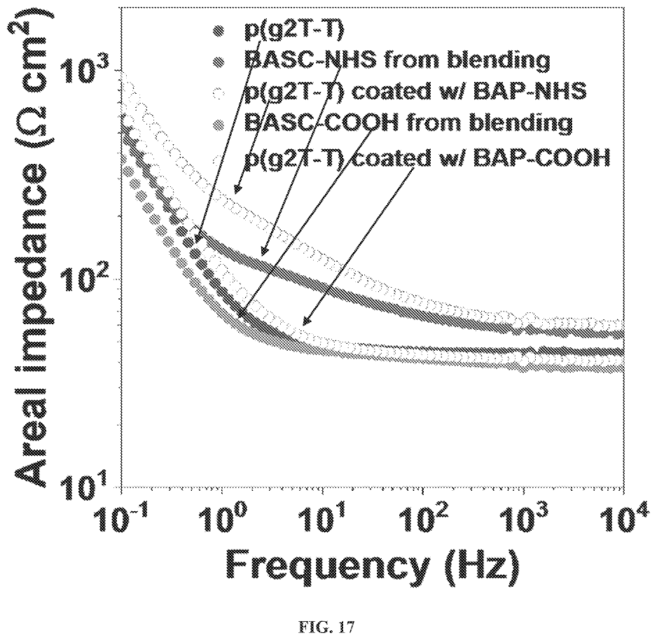

Electrochemical impedance spectroscopy (“EIS”) was used to compare the interfacial impedances from a BASC film, a neat p(g2T-T) film, and a bilayer film with BAP (thickness of 4.5 μm) coated on a neat p(2gT-T) surface. As illustrated in FIG. 16 for measurement in PBS solution, the BASC film gives interfacial impedance comparable to the neat p(g2T-T) film, while the bilayer film demonstrated significantly increased impedance. The comparisons of BASC-NHS and BASC-COOH films further demonstrated the importance of the side-chain hydrophilicity in BAPs for decreasing the interfacial impedance, as illustrated in FIG. 17.

### D. BASC Film Abrasion Resistance, Stretchability, and Biocompatibility

During the insertion and/or attachment of a device into or onto biological tissues, and during the operation of the device, physical abrasion may be exerted on the device surface. With conjugated polymers typically having relatively low toughness, BASC films may be generally susceptible to abrasions. BASC films of the present disclosure, demonstrate great abrasion-resistance, which may be due to the ultrasoft and viscoelastic properties of the films. A piece of glass was slid back and forth on a BASC film under a pressure of 1 kPa. After 1,000 cycles of such surface sliding, the BASC film remained mostly intact in both appearance under an optical microscope and in electrical performance in an OECT device. By comparison, a neat p(g2T-T) film was severely damaged by such surface abrasion processes.

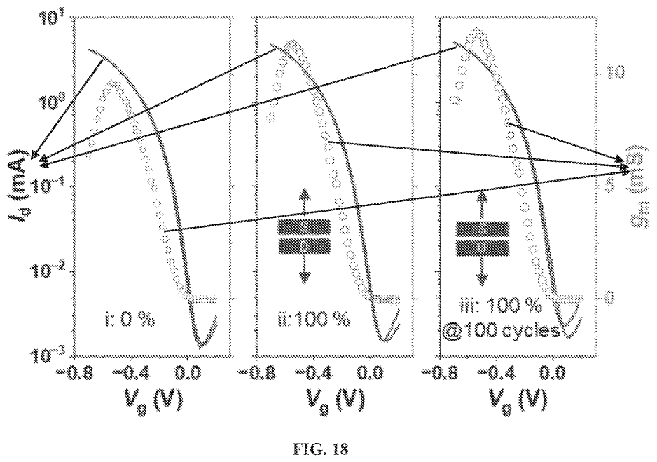

BASC films of the present disclosure demonstrate high stretchability, which may benefit conformability to curvilinear tissue surfaces and robustness under tissue deformations. From optical microscopy and atomic force microscopy (“AFM”) images, the BASC film may be stretched to 100% strain without forming any cracks. Instead, strain-induced alignment of p(g2T-T) nanofibers was observed. When tested in OECT devices, the BASC films of the present disclosure demonstrated highly stable electrical performance during stretching to 100% strain, even after 100 repeated cycles, as illustrated in FIG. 18.

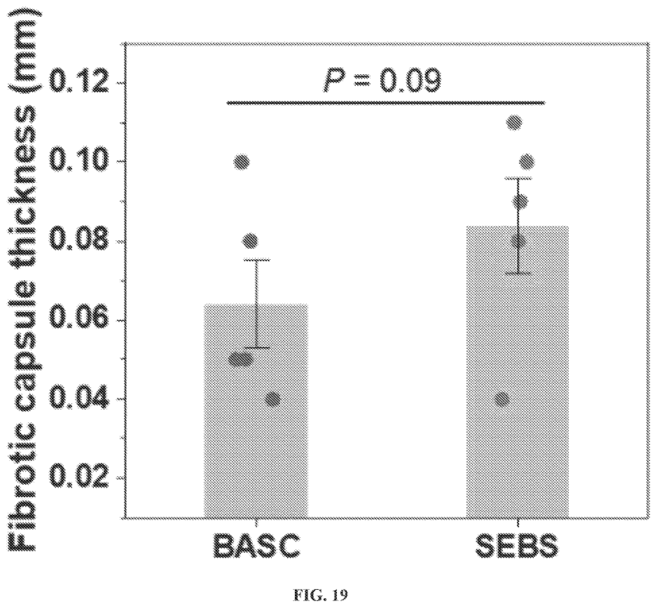

The foreign-body response (“FBR”) may limit the longevity of a device that is interfaced with tissue. The FBR may be largely influenced by the mechanical modulus and the surface chemical property of an implant. BASC films were laminated on both sides of polystyrene-block-poly(ethylene-ran-butylene)-block-polystyrene (“SEBS”) substrates, and implanting the films subcutaneously in mice. At one month after implantation, fibrotic capsules had formed around the BASC film samples that were thinner than those formed around SEBS control samples, as illustrated in FIG. 19. Immunofluorescence imaging of FBR-related biomarkers (such as α-SMA and CD68) demonstrate lower amounts of fibroblasts and macrophages deposited on the BASC surface than those on the SEBS samples. Therefore, the BASC films of the present disclosure have a high level of biocompatibility.

### E. Fully-Bioadhesive OECT-Based Sensors

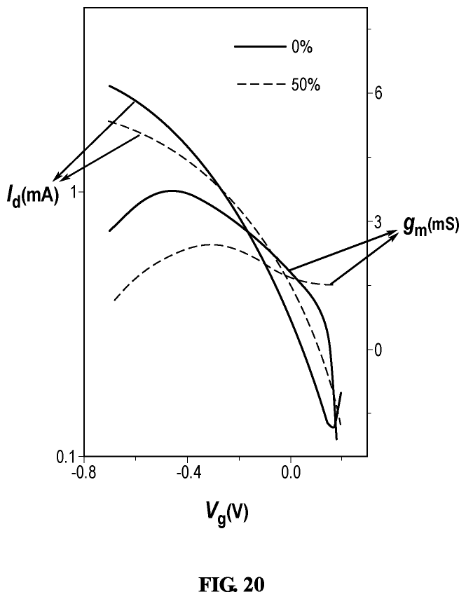

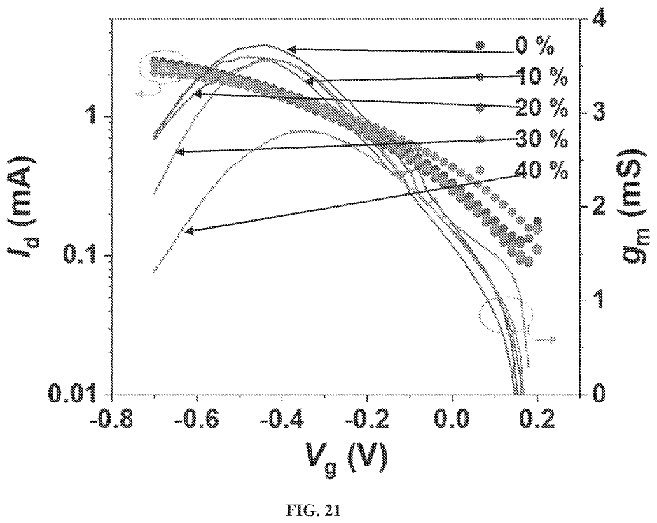

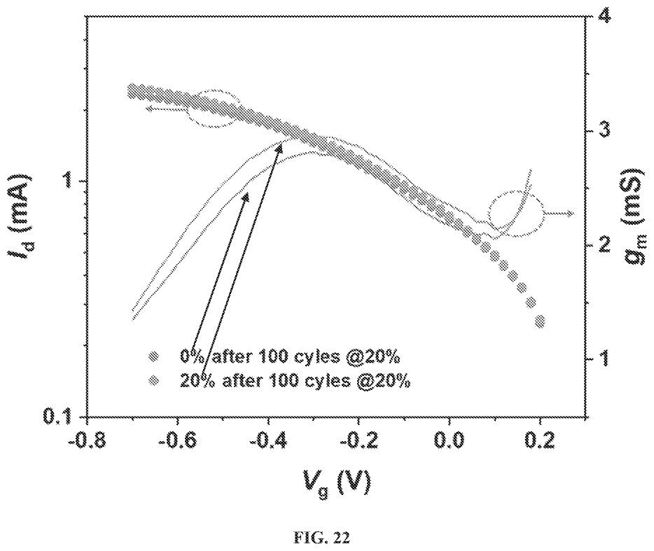

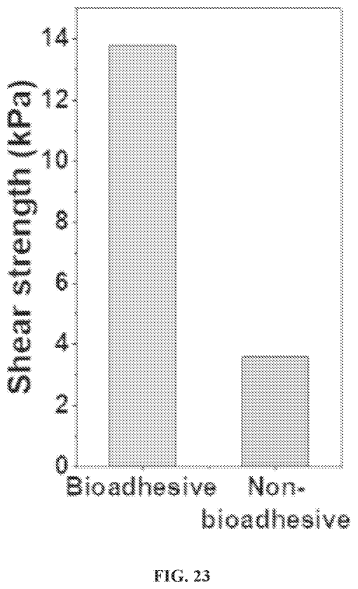

A fully-bioadhesive OECT-based sensor was designed and fabricated including BASC films as both the semiconducting channel and the redox-active gate. The surrounding area was occupied by the substrate, which was covered by the BAP film so as to achieve the fully bioadhesive property at the sensing zone. With the use of microcrack-based stretchable gold as the electrodes and thin SEBS layers (~570-nanometers thick) as the encapsulation for the interconnects and the bottom side of the electrodes, the OECT sensor was also stretchable. As illustrated in FIG. 20, a fully-bioadhesive OECT sensor demonstrated excellent transfer behavior, with high transconductance (~2 mS) presenting near-zero gate voltage. When stretched to 50% strain, the performance was well maintained, as illustrated in FIGS. 21-22. When attached to the surface of wet porcine muscle tissue, the OECT sensor forms a strong adhesion with a shear strength of over 13 kPa, as illustrated in FIG. 23, which is 3 times stronger than a non-bioadhesive OECT control sensor.

The benefit of the bioadhesive property of the OECT sensor was demonstrated on epicardial electrocardiogram (“ECG”) recording from an isolated heart rat. The bioadhesive OECT may be conveniently adhered to the wet heart surface by gently pressing for 20 seconds. As the ECG signal couples into the OECT sensor as a potential difference between the semiconducting channel and gate electrode, the BASC films may enable conformable and stable interfacing for low-impedance signal transduction. During the recording process, the bioadhesive and stretchable properties, working in conjunction, helped the OECT to accommodate the heart beating, thereby maintaining spatially stable and conformable contact on the heart. Thus, the ECG recording from both left ventricle (“LV”) and right ventricle (“RV”) surfaces remained highly stable, with the signal pattern agreeing with the recorded ventricular pressure (“VP”). By comparison, for a non-bioadhesive OECT, which may only stay on the tissue surface through capillary force form the fluid, gradual drifting and even complete detachment may occur as a result of the heart beating or mechanical agitation, significantly impacting the quality and stability of ECG recording. Bioadhesion thus greatly benefits bio-interfacing applications of transistor-based advanced sensing that generate high signal amplitudes.

Although the present disclosure has been described with reference to examples and the accompanying drawings, the present disclosure is not limited thereto, but may be variously modified and altered by those skilled in the art to which the present disclosure pertains without departing from the spirit and scope of the present disclosure.

The subject-matter of the disclosure may also relate, among others, to the following aspects:

A first aspect relates to a bioadhesive polymer semiconductor (“BASC”) film, comprising: a semiconducting polymer; and a bioadhesive polymer; wherein the film is a multi-network film.

A second aspect relates to the film of aspect 1, wherein the film is a double-network film.

A third aspect relates to the film of aspect 1 or 2, wherein the bioadhesive polymer comprises a polyethylene backbone.

A fourth aspect relates to the film of aspect 1 or 2, wherein the bioadhesive polymer comprises a polyether backbone.

A fifth aspect relates to the film of aspect 1 or 2, wherein the bioadhesive polymer comprises a polyester backbone.

A sixth aspect relates to the film of aspect 1 or 2, wherein the bioadhesive polymer comprises a polynorbornene backbone.

A seventh aspect relates to the film of any preceding aspect, wherein the bioadhesive polymer comprises side chains comprising alkyl units.

An eighth aspect relates to the film of any one of aspects 1 to 6, wherein the bioadhesive polymer comprises side chains comprising poly(ethylene glycol) units.

A ninth aspect relates to the film of aspect 8, wherein the side chains comprise tetra(ethylene glycol) units.

A tenth aspect relates to the film of any one of aspects 1 to 6, wherein the bioadhesive polymer comprises side chains comprising a terminal functional group selected from the group consisting of a carboxylic acid, a catechol, an aldehyde, a cyanoacrylate, an isocyanate, an aryl azide, and a NHS ester group.

An eleventh aspect relates to the film of any preceding aspect, wherein the bioadhesive polymer is a polymer of formula (I):

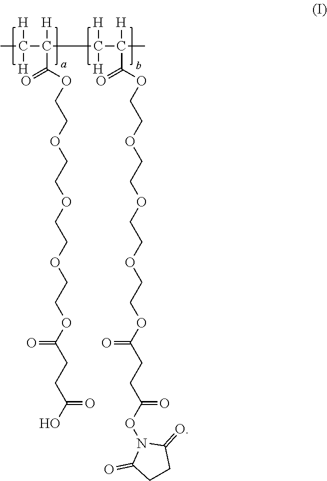

A twelfth aspect relates to the film of any preceding aspect, wherein the semiconducting polymer comprises a π-conjugated backbone.

A thirteenth aspect relates to the film of any preceding aspect, wherein the semiconducting polymer comprises side chains comprising alkyl units.

A fourteenth aspect relates to the film of any one of aspects 1 to 12, wherein the semiconducting polymer comprises side chains comprising oligo(ethylene glycol) units.

A fifteenth aspect relates to the film of aspect 14, wherein the side chains comprise tri(ethylene glycol) units.

A sixteenth aspect relates to the film of any preceding aspect, wherein the semiconducting polymer is a polymer of formula (IV):

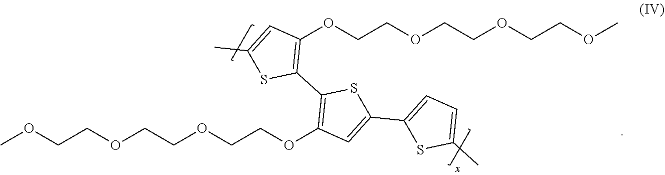

A seventeenth aspect relates to a method of making a bioadhesive polymer semiconductor (“BASC”) film, comprising: preparing a solution of a semiconducting polymer; adding a monomer to the solution to provide a combined solution; applying the combined solution to a substrate to provide a coated substrate; exposing the coated substrate to ultraviolet radiation to provide a crosslinked film; and heating the crosslinked film to provide the BASC film.

An eighteenth aspect relates to the method of aspect 17, wherein the film is a multi-network film.

A nineteenth aspect relates to the method of aspect 17 or 18, wherein the film is a double-network film.

A twentieth aspect relates to the method of any one of aspects 17 to 19, wherein the monomer is a compound of formula (II):

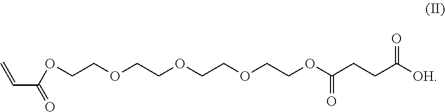 [SMILES: C=CC(=O)OCCOCCOCCOCCOC(=O)CCC(=O)O]

A twenty-first aspect relates to the method of any one of aspects 17 to 19, wherein the monomer is a compound of formula (III):

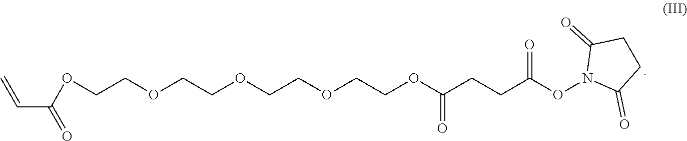 [SMILES: C=CC(=O)OCCOCCOCCOCCOC(=O)CCC(=O)ON1C(=O)CCC1=O]

A twenty-second aspect relates to the method of any one of aspects 17 to 21, wherein the monomer comprises a compound of formula (II) and a compound of formula (III):

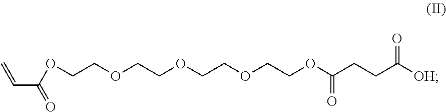 [SMILES: C=CC(=O)OCCOCCOCCOCCOC(=O)CCC(=O)O]

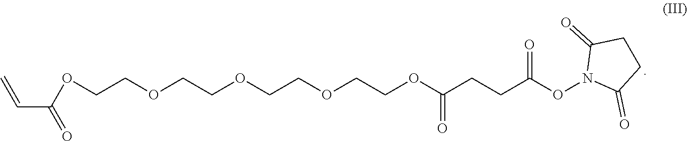 [SMILES: C=CC(=O)OCCOCCOCCOCCOC(=O)CCC(=O)ON1C(=O)CCC1=O]

A twenty-third aspect relates to the method of aspect 22, wherein a mass ratio of the monomer of the compound of formula (II) to the compound of formula (III) is a ratio from 0:100 to 100:0.

A twenty-fourth aspect relates to the method of any one of aspects 17 to 23, wherein the semiconducting polymer comprises a π-conjugated backbone.

A twenty-fifth aspect relates to the method of any one of aspects 17 to 24, wherein the semiconducting polymer comprises side chains comprising alkyl units.

A twenty-sixth aspect relates to the method of any one of aspects 17 to 24, wherein the semiconducting polymer comprises side chains comprising oligo(ethylene glycol) units.

A twenty-seventh aspect relates to the method of aspect 26, wherein the side chains comprise tri(ethylene glycol) units.

A twenty-eighth aspect relates to the method of any one of aspects 17 to 27, wherein the semiconducting polymer is a polymer of formula (IV):

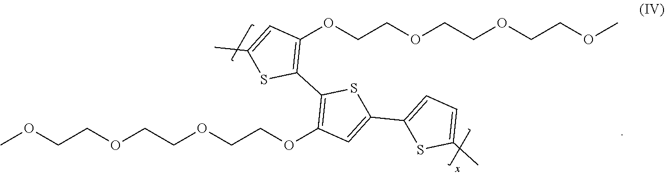

A twenty-ninth aspect relates to the method of any one of aspects 17 to 28, wherein the ultraviolet radiation is at a wavelength of from 200 nanometers to 600 nanometers.

A thirtieth aspect relates to the method of any one of aspects 17 to 29, wherein the heating is at a temperature of at least 60° C.

A thirty-first aspect relates to the method of any one of aspects 17 to 30, further comprising adding a crosslinker to the combined solution prior to the applying.

A thirty-second aspect relates to the method of any one of aspects 17 to 30, further comprising adding a photoinitiator to the combined solution prior to the applying.

A thirty-third aspect relates to the method of any one of aspects 17 to 30, further comprising adding a thermal initiator to the combined solution prior to the applying.

A thirty-fourth aspect relates to a method of making a bioadhesive polymer semiconductor (“BASC”) film, comprising: preparing a solution of a semiconducting polymer; adding a pre-polymerized bioadhesive polymer to the solution to the provide a combined solution; applying the combined solution to a substrate to provide a coated substrate; and heating the coated substrate to provide the BASC film.

A thirty-fifth aspect relates to the method of aspect 34, wherein the film is a multi-network film.

A thirty-sixth aspect relates to the method of aspect 34 or 35, wherein the film is a double-network film.

A thirty-seventh aspect relates to the method of any one of aspects 34 to 36, wherein the pre-polymerized bioadhesive polymer is a polymer of formula (I):

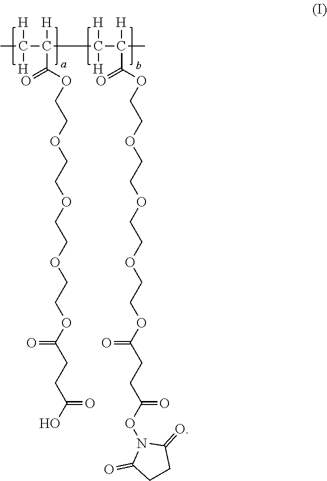

A thirty-eighth aspect relates to the method of any one of aspects 34 to 37, wherein the pre-polymerized bioadhesive polymer is polymerized from a mixture comprising a compound of formula (II) and/or a compound of formula (III):

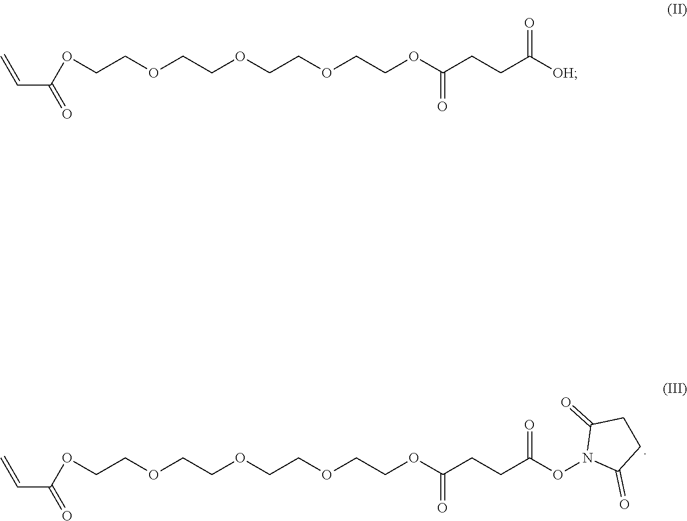 [SMILES: C=CC(=O)OCCOCCOCCOCCOC(=O)CCC(=O)O ; C=CC(=O)OCCOCCOCCOCCOC(=O)CCC(=O)ON1C(=O)CCC1=O]

A thirty-ninth aspect relates to the method of aspect 38, wherein a mass ratio of the compound of formula (II) to the compound of formula (III) is a ratio of from 0:100 to 100:0.

A fortieth aspect relates to the method of any one of aspects 34 to 39, wherein the semiconducting polymer comprises a π-conjugated backbone.

A forty-first aspect relates to the method of any one of aspects 34 to 40, wherein the semiconducting polymer comprises side chains comprising alkyl units.

A forty-second aspect relates to the method of any one of aspects 34 to 40, wherein the semiconducting polymer comprises side chains comprising oligo(ethylene glycol) units.

A forty-third aspect relates to the method of aspect 42, wherein the side chains comprise tri(ethylene glycol units).

A forty-fourth aspect relates to the method of any one of aspects 34 to 43, wherein the semiconducting polymer is a polymer of formula (IV):

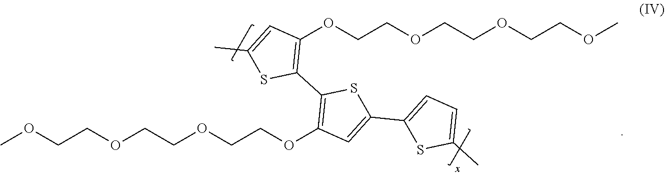

A forty-fifth aspect relates to the method of any one of aspects 34 to 44, wherein the ultraviolet radiation is at a wavelength of from 200 to 600 nanometers.

A forty-sixth aspect relates to the method of any one of aspects 34 to 45, wherein the heating is at a temperature of at least 60° C.

A forty-seventh aspect relates to an organic electrochemical transistor (“OECT”), comprising a bioadhesive polymer semiconductor (“BASC”) film, the film comprising: semiconducting polymer; and a bioadhesive polymer; wherein the film is a multi-network film.

A forty-eighth aspect relates to the transistor of aspect 47, wherein the film is a double-network film.

A forty-ninth aspect relates to the transistor of aspect 47 or 48, wherein the bioadhesive polymer comprises a backbone comprising polyethylene, polyether, polyester, or polynorbornene.

A fiftieth aspect relates to the transistor of any one of aspects 47 to 49, wherein the bioadhesive polymer comprises side chains comprising alkyl units.

A fifty-first aspect relates to the transistor of any one of aspects 47 to 49, wherein the bioadhesive polymer comprises side chains comprising poly(ethylene glycol) units.

A fifty-second aspect relates to the transistor of aspect 51, wherein the side chains comprise tetra(ethylene gycol) units.

A fifty-third aspect relates to the transistor of any one of aspects 47 to 49, wherein the bioadhesive polymer comprises side chains comprising a terminal functional group selected from the group consisting of a carboxylic acid, a catechol, an aldehyde, a cyanoacrylate, an isocyanate, an aryl azide, and a NHS ester group.

A fifty-fourth aspect relates to the transistor of any one of aspects 47 to 53, wherein the bioadhesive polymer is a polymer of formula (I):

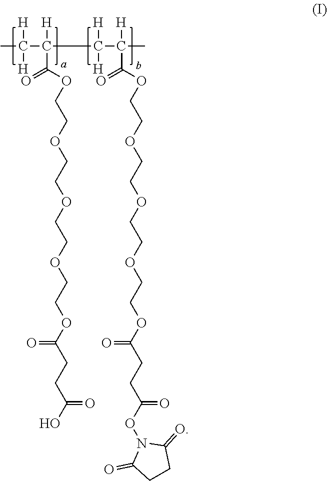

A fifty-fifth aspect relates to the transistor of any one of aspects 47 to 54, wherein the semiconducting polymer comprises a π-conjugated backbone.

A fifty-sixth aspect relates to the transistor of any one of aspects 47 to 55, wherein the semiconducting polymer comprises side chains comprising alkyl units.

A fifty-seventh aspect relates to the transistor of any one of aspects 47 to 55, wherein the semiconducting polymer comprises side chains comprising oligo(ethylene glycol) units.

A fifty-eighth aspect relates to the transistor of aspect 57, wherein the side chains comprise tri(ethylene glycol) units.

A fifty-ninth aspect relates to the transistor of any one of aspects 47 to 58, wherein the semiconducting polymer is a polymer of formula (IV):

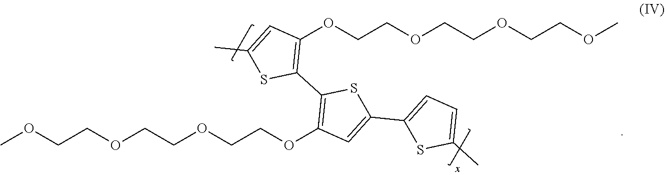

In addition to the features mentioned in each of the independent aspects enumerated above, some examples may show, alone or in combination, the optional features mentioned in the dependent aspects and/or as disclosed in the description above and shown in the figures.

1. A bioadhesive polymer semiconductor (“BASC”) film, comprising:
a semiconducting polymer; and
a bioadhesive polymer;
wherein the film is a multi-network film.

2. The film of claim 1, wherein the film is a double-network film.

3. The film of claim 1, wherein the bioadhesive polymer comprises a polyethylene backbone comprising polyethylene, polyether, polyester, or polynorbornene.

4-9. (canceled)

10. The film of claim 1, wherein the bioadhesive polymer comprises side chains comprising a terminal functional group selected from the group consisting of a carboxylic acid, a catechol, an aldehyde, a cyanoacrylate, an isocyanate, an aryl azide, and a NHS ester group.

11. The film of claim 1, wherein the bioadhesive polymer is a polymer of formula (I):

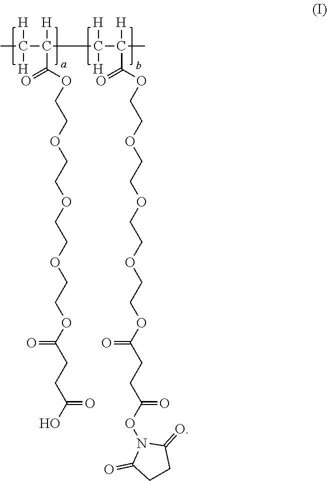

12. The film of claim 1, wherein the semiconducting polymer comprises π-conjugated backbone, side chains comprising alkyl units, side chains comprising oligo(ethylene glycol) units, or side chains comprising tri(ethylene glycol) units.

13-15. (canceled)

16. The film of claim 1, wherein the semiconducting polymer is a polymer of formula (IV):

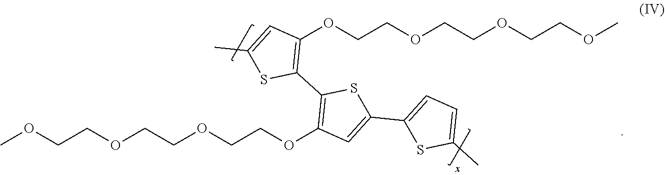

17. A method of making a bioadhesive polymer semiconductor (“BASC”) film, comprising:
preparing a solution of a semiconducting polymer;
adding a monomer to the solution to provide a combined solution;
applying the combined solution to a substrate to provide a coated substrate;
exposing the coated substrate to ultraviolet radiation to provide a crosslinked film; and
heating the crosslinked film to provide the BASC film.

18-21. (canceled)

22. The method of claim 17, wherein the monomer comprises a compound of formula (II) and/or a compound of formula (III):

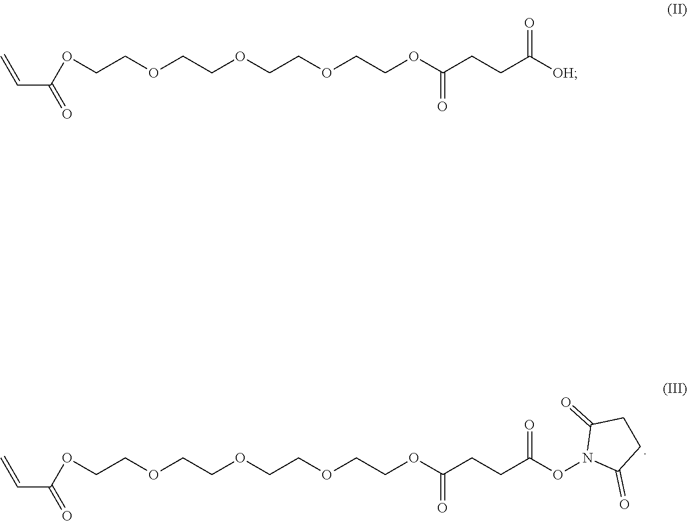 [SMILES: C=CC(=O)OCCOCCOCCOCCOC(=O)CCC(=O)O ; C=CC(=O)OCCOCCOCCOCCOC(=O)CCC(=O)ON1C(=O)CCC1=O]

23. (canceled)

24. The method of claim 17, wherein the semiconducting polymer comprises a π-conjugated backbone, side chains comprising alkyl units, side chains comprising oligo(ethylene glycol) units, or side chains comprising tri(ethylene glycol) units.

25-27. (canceled)

28. The method of claim 17, wherein the semiconducting polymer is a polymer of formula (IV):

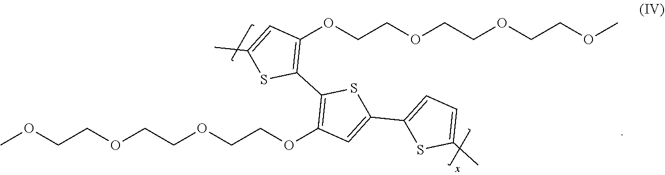

29-33. (canceled)

34. A method of making a bioadhesive polymer semiconductor (“BASC”) film, comprising:
preparing a solution of a semiconducting polymer;
adding a pre-polymerized bioadhesive polymer to the solution to provide a combined solution;
applying the combined solution to a substrate to provide a coated substrate; and
heating the coated substrate to provide the BASC film.

35-36. (canceled)

37. The method of claim 34, wherein the pre-polymerized bioadhesive polymer is a polymer of formula (I):

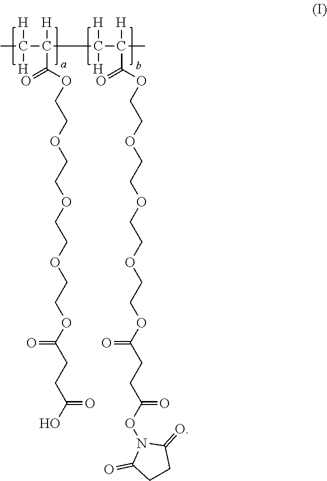

38. The method of claim 34, wherein the pre-polymerized bioadhesive polymer is polymerized from a mixture comprising a compound of formula (II) and/or a compound of formula (III):

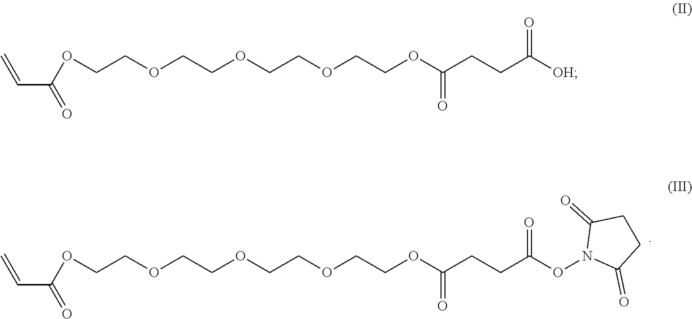 [SMILES: C=CC(=O)OCCOCCOCCOCCOC(=O)CCC(=O)O ; C=CC(=O)OCCOCCOCCOCCOC(=O)CCC(=O)ON1C(=O)CCC1=O]

39. (canceled)

40. The method of claim 34, wherein the semiconducting polymer comprises a π-conjugated backbone, side chains comprising alkyl units, side chains comprising oligo(ethylene glycol) units, or side chains comprising tri(ethylene glycol) units.

41-43. (canceled)

44. The method of claim 34, wherein the semiconducting polymer is a polymer of formula (IV):

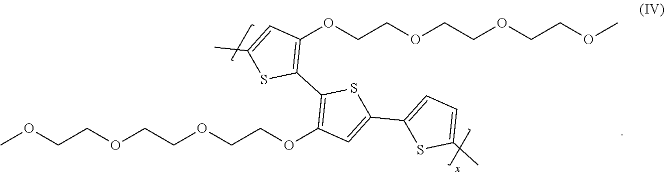

45-46. (canceled)

47. An organic electrochemical transistor (“OECT”), comprising a bioadhesive polymer semiconductor (“BASC”) film, the film comprising:
a semiconducting polymer; and
a bioadhesive polymer;
wherein the film is a multi-network film.

48-53. (canceled)

54. The transistor of claim 47, wherein the bioadhesive polymer is a polymer of formula (I):

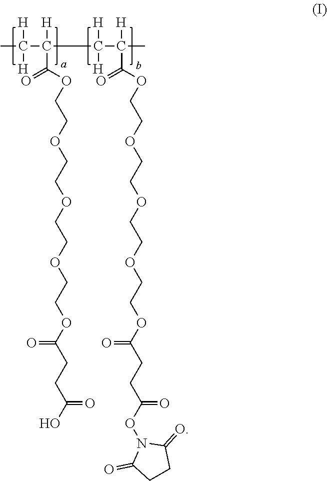

55. The transistor of claim 47, wherein the semiconducting polymer comprises a π-conjugated backbone, side chains comprising alkyl units, side chains comprising oligo(ethylene glycol) units, or side chains comprising tri(ethylene glycol) units.

56-58. (canceled)

59. The transistor of claim 47, wherein the semiconducting polymer is a polymer of formula (IV): [chemical structure]
